(19) United States
(12) Patent Application Publication
(10) Pub. No.: US 2025/0234616 A1
(43) Pub. Date: Jul. 17, 2025

(54) SEMICONDUCTOR STRUCTURE AND METHOD FOR FORMING THE SAME

(71) Applicant: TAIWAN SEMICONDUCTOR MANUFACTURING COMPANY, LTD., Hsinchu (TW)

(72) Inventors: Ta-Chun LIN, Hsinchu (TW); Jhon-Jhy Liaw, Zhudong Township (TW)

(73) Assignee: TAIWAN SEMICONDUCTOR MANUFACTURING COMPANY, LTD., Hsinchu (TW)

(21) Appl. No.: 18/412,272

(22) Filed: Jan. 12, 2024

(51) Int. Cl. H01L 29/417; H01L 21/768; H01L 29/06; H01L 29/423; H01L 29/66; H01L 29/775; H01L 29/786

(52) U.S. Cl. CPC H10D 64/251; H01L 21/76802; H10D 30/014; H10D 30/43; H10D 30/6735; H10D 30/6757; H10D 62/121; H10D 64/017

(57) ABSTRACT

A method of forming a semiconductor structure includes forming a fin structure over a substrate; forming first and second source/drain trenches in the fin structure; forming first and second SiGe layers in the first and second source/drain trenches, respectively; and forming first and second source/drain features over the first and second SiGe layers in the first and second source/drain trenches, respectively. The method further includes forming a first interlayer dielectric (ILD) layer on a backside of the substrate; etching the first ILD layer and the substrate to form a first opening that exposes the first SiGe layer; removing the first SiGe layer to form a second opening that exposes the first source/drain feature; and depositing a conductive material in the first and second openings to form a first source/drain contact. The lateral dimensions of the first opening are greater than those of the second opening.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been introduced to improve gate control by increasing gate-channel coupling, reducing off-state current, and reducing short-channel effects (SCEs). As GAA devices continue to be developed, complementary metal-oxide-semiconductor field effect transistors (CMOSFET or CFET) has been provided due to their high noise immunity and low static power consumption. However, although existing technologies for fabricating CFETs have been generally adequate for their intended purposes, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a Y-Z cross-sectional view of a semiconductor device, in accordance with some embodiments of the present disclosure.

FIG. 1B is an X-Z cross-sectional view of the semiconductor device, in accordance with some embodiments of the present disclosure.

FIG. 2A is a Y-Z cross-sectional view of the semiconductor device, in accordance with some alternative embodiments of the present disclosure.

FIG. 2B is an X-Z cross-sectional view of the semiconductor device, in accordance with some alternative embodiments of the present disclosure.

FIGS. 3, 5, and 7 are Y-Z cross-sectional views of the semiconductor devices, in accordance with some alternative embodiments of the present disclosure.

FIGS. 4, 6, and 8 are X-Z cross-sectional views of the semiconductor devices, in accordance with some alternative embodiments of the present disclosure.

FIG. 9A is a Y-Z cross-sectional view of the semiconductor device, in accordance with some alternative embodiments of the present disclosure.

FIG. 9B is an X-Z cross-sectional view of the semiconductor device, in accordance with some alternative embodiments of the present disclosure.

FIG. 10A is a Y-Z cross-sectional view of the semiconductor device, in accordance with some alternative embodiments of the present disclosure.

FIG. 10B is an X-Z cross-sectional view of the semiconductor device, in accordance with some alternative embodiments of the present disclosure.

FIG. 11A is a Y-Z cross-sectional view of the semiconductor device, in accordance with some alternative embodiments of the present disclosure.

FIG. 11B is an X-Z cross-sectional view of the semiconductor device, in accordance with some alternative embodiments of the present disclosure.

FIG. 12 is a perspective view of a workpiece at a fabrication stage, in accordance with some embodiments of the present disclosure.

FIGS. 13, 14, 15A, 16A, 17A, 18A, 19A, 20A, 21A, 22A, 23A, 24A, 29A, 30A, 31A, 32A, 33A, 34A, 35, 36, 39, and 40 are Y-Z cross-sectional views of the workpiece at various fabrication stages along line C-C′ of FIG. 12, in accordance with some embodiments of the present disclosure.

FIGS. 16B, 17B, 18B, 19B, 20B, 21B, 22B, 23B, 24B, 25A, 26A, 27A, 28A, 29B, 30B, 31B, 32B, 33B, 34B, 37, 38, 41, and 42 are X-Z cross-sectional views of the workpiece at various fabrication stages along line D-D′ of FIG. 12, in accordance with some embodiments of the present disclosure.

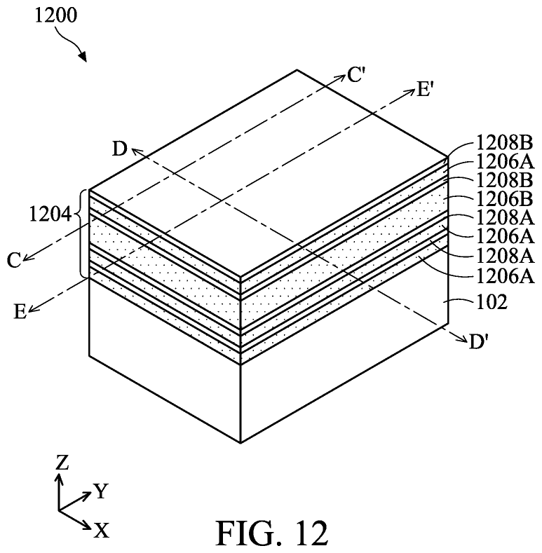

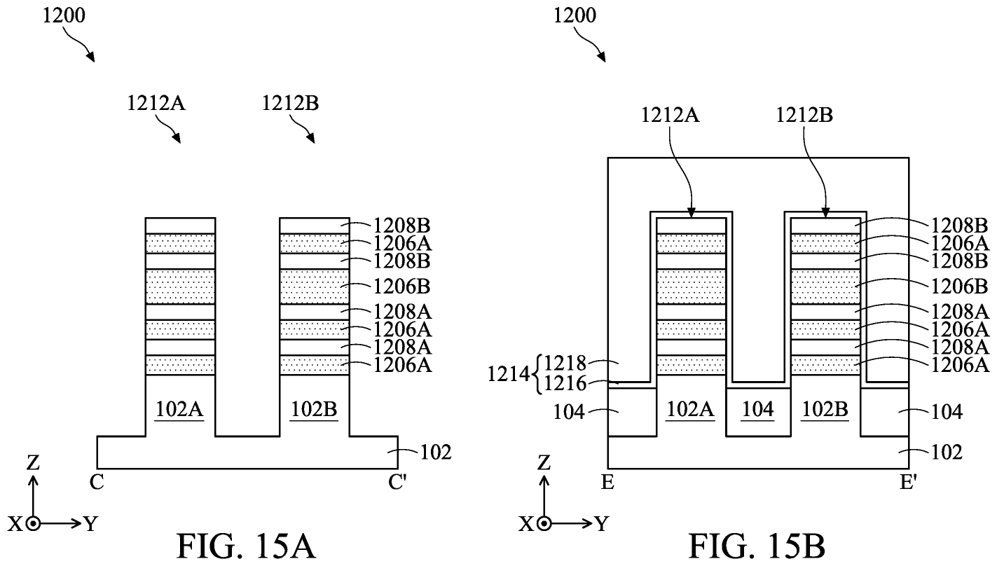

FIGS. 15B, 25B, 26B, 27B, and 28B are Y-Z cross-sectional views of the workpiece at various fabrication stages along line E-E′ of FIG. 12, in accordance with some embodiments of the present disclosure.

FIGS. 43A and 43B are X-Z cross-sectional views of the workpiece, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor devices, and more particularly to field-effect transistors (FETs), such as three-dimensional complementary field effect transistors (CFETs) with gate-all-around (GAA) structures. Generally, a CFET may include an n-type FET (NFET) and a p-type FET (PFET) disposed vertically with a plurality of vertically stacked sheets (e.g., nanosheets), wires (e.g., nanowires), or rods (e.g., nanorods) in a channel region of the CFET, thereby allowing better gate control, lowered leakage current, and improved scaling capability for various IC applications.

The GAA structures may be patterned by any suitable method. For example, the GAA structures may be patterned using one or more photolithography processes, including double-patterning or multi-patterning processes. Generally speaking, double-patterning or multi-patterning processes combine photolithography and self-aligned processes, allowing patterns to be created that have, for example, pitches smaller than what is otherwise obtainable using a single, direct photolithography process. For example, in some embodiments, a sacrificial layer is formed over a substrate and is patterned using a photolithography process. Spacers are formed alongside the patterned sacrificial layer using a self-aligned process. The sacrificial layer is then removed, and the remaining spacers may then be used to pattern the GAA structure.

In advanced technology node, since the geometry size is decreased, the metal routing of the interconnection structure constrained on the frontside of the device may not provide interconnection that is good enough. For example, the resistive-capacitive (RC) delay caused by the metal routing constrained on the frontside may be increased due to the decreased geometry size. Therefore, a backside metal routing disposed on the backside of the device is required, so that the frontside and backside metal routing can together provide better interconnection. However, in the existing technology, since the fabrication of the backside contact and via is still challenging, the size of the backside contact and via are made be relatively small to avoid causing a short-circuit with other components. The smaller backside contact and via cause higher resistance. Therefore, a novel structure and fabricating method are needed to enlarge the dimensions of the backside contact and via, so as to reduce the resistance while avoiding the occurrence of a short-circuit with other components (e.g., metal gate).

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures that have silicon germanium (SiGe) layers formed below the source/drain (S/D) features of the bottom FET in the CFET. When a bottom S/D contact is formed from the backside of the CFET to contact the S/D feature of the bottom FET, the SiGe layer can be selectively removed to form an opening for forming the bottom S/D contact. In this way, the bottom S/D contact can be formed by a self-aligned process that can keep the bottom S/D contact from contacting other conductive components. As a result, the dimensions of the bottom S/D contact can be enlarged as much as possible, so as to reduce the resistance while avoiding the occurrence of a short-circuit with other conductive components.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated.

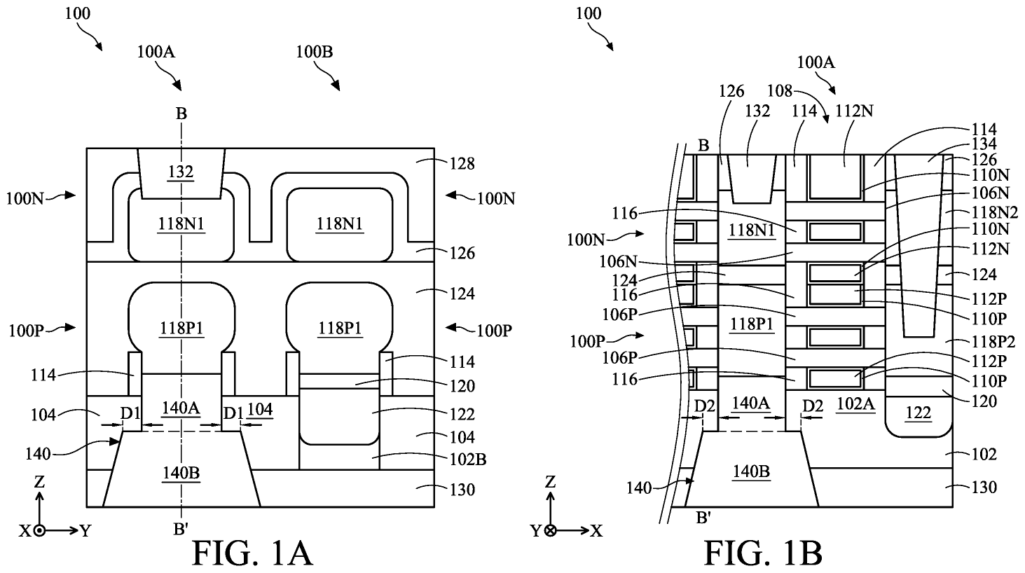

FIG. 1A is a Y-Z cross-sectional view of a semiconductor device 100, in accordance with some embodiments of the present disclosure. FIG. 1B is an X-Z cross-sectional view of the semiconductor device 100 along line B-B′ of FIG. 1A, in accordance with some embodiments of the present disclosure.

Referring to FIGS. 1A and 1B, the semiconductor device 100 includes two complementary field effect transistors (CFETs) 100A and 100B, in accordance with some embodiments. The CFETs 100A and 100B are arranged in the Y-direction, as shown in FIG. 1A. The CFETs 100A and 100B have similar structure and features. Furthermore, each of the CFETs 100A and 100B has a p-type field effect transistor (PFET) 100P and an n-type field effect transistors (NFETs) 100N. In each of the CFETs 100A and 100B, the NFET 100N is disposed over the PFET 100P in the Z-direction, as shown in FIGS. 1A and 1B. In other embodiments, the PFET may be disposed over the NFET in the Z-direction.

The semiconductor device 100 further includes a substrate 102, as shown in FIGS. 1A and 1B. The substrate 102 includes a base portion 102A for the CFET 100A and a base portion 102B for the CFET 100B, which are protruded from the substrate 102 under the nanostructures 106P and 106N. Subsequent features for the CFETs 100A and 100B are formed over the base portions 102A and 102B of the substrate 102, as described in further detail below. In some embodiments, after the resultant NFETs 100N and PFETs 100P of the CFETs 100A and 100B are formed, the substrate 102 may be thinned (or partially removed) by a suitable process (e.g., a chemical mechanical polishing (CMP) process) for forming backside interconnection.

In some embodiments, the semiconductor device 100 further includes isolation structures 104 in and/or over the substrate 102. The isolation structures 104 are formed between the base portions 102A and 102B of the substrate 102. In some embodiments, top surfaces of the isolation structures 104 are lower than top surfaces of the substrate 102 (more specifically, top surfaces of the base portions 102A and 102B).

Still referring to FIGS. 1A and 1B, the semiconductor device 100 further includes two groups of nanostructures, such as a group of the nanostructures 106P and a group of the nanostructures 106N (may be collectively referred to as the nanostructures 106), in accordance with some embodiments. In some embodiments, the nanostructures 106 may also be referred to as channels, channel layers, nanosheets, or nanowires. In some embodiments, the nanostructures 106N are disposed over the nanostructures 106P. The nanostructures 106P are used for the PFETs in the CFETs and the nanostructures 106N are used for the NFETs in the CFETs. Furthermore, the nanostructures 106 are suspended over the base portions 102A and 102B of the substrate 102.

In some embodiments, the nanostructures 106 are extended in the X-direction and vertically stacked (or arranged) in the Z-direction. Specifically, the nanostructures 106 are spaced apart from each other in the Z-direction. In some embodiments, the distance between the topmost nanostructure 106P and the bottommost nanostructure 106N is greater than the distance between two nanostructures 106P or the distance between two nanostructures 106N, as shown in FIG. 1B.

In the embodiment depicted in FIG. 1B, two nanostructures 106 are vertically stacked (or vertically arranged) from each other in the Z-direction for one transistor. For example, in CFET 100A, the NFET 100N has two nanostructures 106N vertically stacked from each other in the Z-direction, and the PFET 100P has two nanostructures 106P vertically stacked from each other in the Z-direction. However, there may be another appropriate number of nanostructures in one transistor. For example, there may be 1, 2, 3, 4, or more than 4 nanostructures 106 in one transistor.

In some embodiments, the semiconductor device 100 further includes a gate structure 108 wrapping around the nanostructures 106. More specifically, the gate structure 108 wraps around the nanostructures 106P in the PFETs 100P and the nanostructures 106N in the NFETs 100N. The CFETs 100A and 100B share the gate structure 108. More specifically, the gate structure 108 extend in the Y-direction to wrap around the nanostructures 106 in the CFET 100A and the CFET 100B. In some embodiments, the gate structure 108 has a length in the X-direction (i.e., gate length) that is in a range from about 6 nm (nanometer) to about 20 nm.

The gate structure 108 has a gate dielectric layer 110P, a gate electrode layer 112P, a gate dielectric layer 110N, and a gate electrode layer 112N (the gate dielectric layers 110P and 110N may be collectively referred to as the gate dielectric layers 110, and the gate electrode layers 112P and 112N may be collectively referred to as the gate electrode layers 112). As shown in FIG. 1B, the gate dielectric layer 110P wraps around each of the nanostructures 106P in the PFETs 100P, and the gate dielectric layer 110N wraps around each of the nanostructures 106N in the NFETs 100N. The gate electrode layer 112P wraps around the gate dielectric layer 110P and each of the nanostructures 106P in the PFETs 100P, and the gate electrode layer 112N wraps around the gate dielectric layer 110N and each of the nanostructures 106N in the NFETs 100N.

In some embodiments, the gate dielectric layer 110P is also formed on top surfaces of the isolation structures 104 and top surfaces and sidewalls of the substrate 102 (more specifically, the top surfaces and sidewalls of the base portions 102A and 102B) (not shown). The gate dielectric layer 110N is also formed on a top surface of the gate electrode layer 112P, as shown in FIG. 1B. In some embodiments, the gate dielectric layer 110P is further formed on sidewalls of inner spacers 116 (discussed below), and the gate dielectric layer 110N is further formed on sidewalls of the gate spacer 114 (discussed below) and the inner spacers 116, as shown in FIG. 1B. In some embodiments, the gate dielectric layer 110P is in contact with the gate dielectric layer 110N, as shown in FIG. 1B.

In some embodiments, the gate structure 108 further includes an interfacial layer (not shown, such as having silicon dioxide, silicon oxynitride, or other suitable materials) between the gate dielectric layers 110 and the nanostructures 106. As discussed above, the gate electrode layers 112P and 112N are formed to wrap around the gate dielectric layers 110P and 110N and the nanostructures 106, as shown in FIG. 1B.

In some embodiments, the semiconductor device 100 further includes gate spacers 114 on opposite sides of the gate structure 108. More specifically, the gate spacers 114 are on sidewalls of the gate structures 108 and over the nanostructures 106, as shown in FIG. 1B. Furthermore, the gate spacers 114 extend lengthwise in the Y-direction (e.g., parallel to the gate structure 108), and are on opposite sides (or on opposite sidewalls) of the gate structure 108 in the X-direction. The gate spacers 114 are over the nanostructures 106 and on top sidewalls of the gate structures 108, and thus are also referred to as gate top spacers or top spacers.

In some embodiments, the semiconductor device 100 further includes inner spacers 116 on opposite sides of the gate structure 108. More specifically, the inner spacers 116 are on the sidewalls of the gate structure 108, and below the gate spacers 114 and the topmost nanostructure 106N. As shown in FIG. 1B, the inner spacers 116 are also vertically between adjacent nanostructures 106N, vertically between adjacent nanostructures 106N and 106P, vertically between adjacent nanostructures 106P, and vertically between the bottommost nanostructures 106P and the substrate 102, in accordance with some embodiments. In some embodiments, a thickness of the inner spacers 116 vertically between adjacent nanostructures 106N and 106P in the Z-direction is greater than thicknesses of other inner spacers 116, as shown in FIG. 1B. Furthermore, the inner spacers 116 are laterally between the source/drain features 118N/118P (described below) and the gate structure 108 in the X-direction.

Still referring to FIGS. 1A and 1B, each of the CFETs 100A and 100B includes source/drain features 118P1, 118P2 (may be collectively referred to as the source/drain features 118P) and source/drain features 118N1, 118N2 (may be collectively referred to as the source/drain features 118N) over the substrate 102, in accordance with some embodiments. More specifically, the source/drain features 118P1 and 118P2 are disposed over the substrate 102, and the source/drain features 118N1 and 118N2 are disposed over the source/drain features 118P1 and 118P2, respectively. In some embodiments, the source/drain features 118N are vertically separated from the source/drain features 118P in the Z-direction, as shown in FIGS. 1A and 1B. In some embodiments, the source/drain features 118N are disposed on opposite sides of the gate structure 108 in the X-direction to form the NFETs 100N. Similarly, the source/drain features 118P are disposed on opposite sides of the gate structure 108P in the X-direction to form the PFETs 100P, as shown in FIG. 1B.

The nanostructures 106 extend in the X-direction to connect one source/drain feature 118P/118N to the other source/drain feature 118P/118N, in accordance with some embodiments. More specifically, the source/drain features 118P1 and 118P2 are disposed on opposite sides of the nanostructures 106P and the source/drain features 118N1 and 118N2 are disposed on opposite sides of the nanostructures 106N in the X-direction. Therefore, the source/drain features 118P are attached and electrically connected to the nanostructures 106P in the X-direction, and the source/drain features 118N are attached and electrically connected to the nanostructures 106N in the X-direction. The source/drain features 118P/118N may also be referred to as source/drain, or source/drain regions. In some embodiments, source/drain feature(s) may refer to a source or a drain, individually or collectively dependent upon the context.

Still referring to FIGS. 1A and 1B, the semiconductor device 100 further includes bottom isolation layers 120 under the source/drain features 118N and 118P and over the substrate 102 in the Z-direction, in accordance with some embodiments. In some embodiments, the bottom isolation layers 120 are under and in contact with the source/drain feature 118P2 of the CFET 100A, and under and in contact with the source/drain feature 118P1 of the CFET 100B, as shown in FIGS. 1A and 1B. In some embodiments, the top surfaces of the bottom isolation layers 120 are higher than the bottommost surface of the gate structure 108, as shown in FIG. 1B. In some aspects, the top surfaces of the bottom isolation layers 120 are higher than the topmost surfaces of the substrate 102 (i.e., the top surfaces of the base portions 102A and 102B), so as to ensure that the bottom isolation layers 120 separate the source/drain features 118P from the substrate 102.

Still referring to FIGS. 1A and 1B, the semiconductor device 100 further includes SiGe layers 122 under the bottom isolation layers 120, in accordance with some embodiments. More specifically, the SiGe layers 122 are vertically between and in contact with bottom isolation layers 120 and the substrate 102 in the Z-direction. In some embodiments, the SiGe layers 122 are under and in contact with the bottom isolation layer 120 that is under the source/drain feature 118P2 of the CFET 100A, and under and in contact with the bottom isolation layer 120 that is under the source/drain feature 118P1 of the CFET 100B, as shown in FIGS. 1A and 1B.

In some embodiments, a thickness of the SiGe layer 122 in the Z-direction is in a range from about 5 nm to about 50 nm. In some embodiments, the top surfaces of the SiGe layers 122 are higher than the top surfaces of the isolation structures 104, as shown in FIG. 1A. In other embodiments, the top surfaces of the SiGe layers 122 are level with or lower than the top surfaces of the isolation structures 104.

Still referring to FIGS. 1A and 1B, the semiconductor device 100 further includes an interlayer dielectric (ILD) layer 124 over the substrate 102, the isolation structures 104, and the source/drain features 118P, in accordance with some embodiments. In some embodiments, the ILD layer 124 is also between and fill the spaces between the source/drain features 118P in the Y-direction, as shown in FIG. 1A. In these embodiments, the source/drain features 118P are surrounded by the ILD layer 124 in the Y-direction. In some embodiments, the ILD layer 124 is vertically between and in contact with the source/drain features 118P and the source/drain features 118N in the Z-direction. For example, the ILD layer 124 is vertically between the source/drain feature 118P1 and 118N1, and is vertically between the source/drain feature 118P2 and 118N2. Thus, the source/drain features 118P are separated and electrically isolated from the source/drain features 118N by the ILD layer 124.

Still referring to FIGS. 1A and 1B, the semiconductor device 100 further includes contact etch stop layers (CESLs) 126 and an ILD layer 128 over the CESLs 126, in accordance with some embodiments. The CESLs 126 are over the source/drain features 118N and the ILD layer 124, and the ILD layer 128 is formed to fill the space between the source/drain features 118N. More specifically, the CESLs 126 are conformally formed on the sidewalls of the gate spacers 114. In some embodiments, the CESLs 126 are also conformally formed on the top surfaces and the sidewalls of the source/drain features 118N, as shown in FIG. 1A. The ILD layer 128 is formed over and between the CESLs 126 to fill the space in the CESLs 126 and between the gate spacers 114.

Still referring to FIGS. 1A and 1B, the semiconductor device 100 further includes an ILD layer 130 under the substrate 102, in accordance with some embodiments.

Still referring to FIGS. 1A and 1B, the semiconductor device 100 further includes source/drain contacts 132 and 134, in accordance with some embodiments. The source/drain contact 132 passes through the ILD layer 128, the CESLs 126, and portions of the source/drain features 118N, so as to be in contact with and electrically connected to the source/drain features 118N. In some embodiments, the source/drain contact 132 is in contact with and electrically connected to the source/drain feature 118N1 of the CFET 100A, as shown in FIGS. 1A and 1B. The source/drain contact 134 passes through the ILD layer 128, the CESLs 126, the source/drain features 118N, the ILD layer 124, and portions of the source/drain features 118P, so as to be in contact with and electrically connected to both of the source/drain features 118N and 118P. In some embodiments, the source/drain contact 134 is in contact with and electrically connected to the source/drain feature 118N2 and the source/drain feature 118P2 of the CFET 100A, as shown in FIG. 1B.

In some embodiments, the source/drain contacts 132 and 134 may further include sidewall dielectric layers formed on the sidewalls. In these embodiments, the sidewall dielectric layers can improve the isolation between the source/drain contacts 132 and 134 and the gate structure 108 or other source/drain contacts. Since the source/drain contacts 132 and 134 are formed on the frontside of the semiconductor device 100, the source/drain contacts 132 and 134 may be referred to as frontside source/drain contacts.

Still referring to FIGS. 1A and 1B, the semiconductor device 100 further includes source/drain contact 140, in accordance with some embodiments. The source/drain contact 140 passes through the ILD layer 130 and the substrate 102, so as to be in contact with and electrically connected to the source/drain features 118P. In some embodiments, the source/drain contact 140 is in contact with and electrically connected to the source/drain feature 118P1 of the CFET 100A, as shown in FIGS. 1A and 1B. Since the source/drain contact 140 is formed on backside of the semiconductor device 100, the source/drain contact 140 may be referred to as a backside source/drain contact or a bottom source/drain contact.

In some embodiments, the source/drain contact 140 includes a portion 140A that is in contact with the source/drain feature 118P, and a portion 140B that is below the portion 140A in the Z-direction. In some embodiments, a Y-direction width of the portion 140B is greater than a Y-direction width of the portion 140A, as shown in FIG. 1A. In these embodiments, the source/drain contact 140 including the portions 140A and 140B may have a two-step structure in the Y-Z plane. In these embodiments, compared with the portion 140A, the portion 140B has protruding portions that protrude from sidewalls of the portion 140A in the Y-direction by at least a dimension D1. In certain embodiments, the dimension D1 is in a range from about 1 nm to about 10 nm. By enlarging the source/drain contact 140 by a dimension (e.g., the dimension D1) in the Y-direction, the resistance of the source/drain contact 140 may be reduced further. In some embodiments, the interface between the portion 140A and the portion 140B in the Y-Z plane is in the isolation structures 104, but the present disclosure is not limited thereto. For example, the interface between the portion 140A and the portion 140B in the Y-Z plane may be positioned in the ILD layer 130, at the interface between the isolation structures 104 and the ILD layer 130, or at the interface between the ILD layer 124 and the isolation structures 104.

In some embodiments, an X-direction width of the portion 140B is greater than an X-direction width of the portion 140A, as shown in FIG. 1B. In these embodiments, the source/drain contact 140 including the portions 140A and 140B may have a two-step structure in the X-Z plane. In these embodiments, compared with the portion 140A, the portion 140B has protruding portions that protrude from sidewalls of the portion 140A in the X-direction by at least a dimension D2. In certain embodiments, the dimension D2 is in a range from about 1 nm to about 10 nm. By enlarging the source/drain contact 140 by a dimension (e.g., the dimension D2) in the X-direction, the resistance of the source/drain contact 140 may be reduced further. In some embodiments, the interface between the portion 140A and the portion 140B in the X-Z plane is in the substrate 102, but the present disclosure is not limited thereto. For example, the interface between the portion 140A and the portion 140B in the X-Z plane may be positioned in the ILD layer 130 or at the interface between the ILD layer 130 and the substrate 102. In some embodiments, the portion 140A of the source/drain contact 140 is partially in contact with the bottommost one of the inner spacers 116.

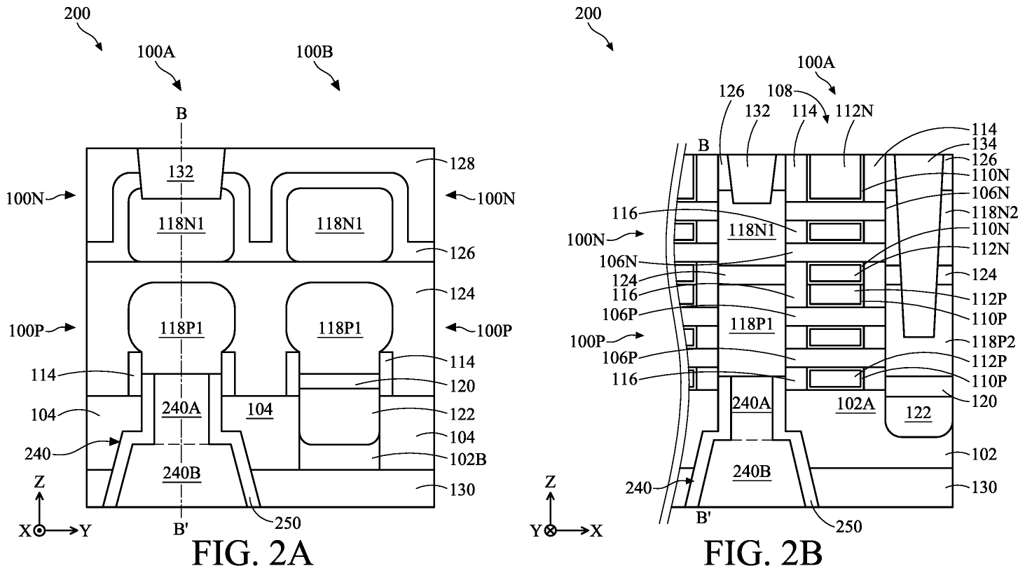

FIG. 2A is a Y-Z cross-sectional view of a semiconductor device 200, in accordance with alternative embodiments of the present disclosure. FIG. 2B is an X-Z cross-sectional view of the semiconductor device 200 along line B-B′ of FIG. 2A, in accordance with alternative embodiments of the present disclosure. The semiconductor device 200 shown in FIGS. 2A and 2B may be similar to the semiconductor device 100 shown in FIGS. 1A and 1B, except the source/drain contact 140 shown in FIGS. 1A and 1B is replaced by a source/drain contact 240 shown in FIGS. 2A and 2B.

Referring to FIGS. 2A and 2B, similar to the source/drain contact 140 shown in FIGS. 1A and 1B, the source/drain contact 240 includes a portion 240A that is in contact with the source/drain feature 118P, and a portion 240B that is below the portion 240A in the Z-direction, in accordance with some embodiments. In some embodiments, a Y-direction width of the portion 240B is greater than a Y-direction width of the portion 240A, as shown in FIG. 2A. In these embodiments, the source/drain contact 240 including the portions 240A and 240B may have a two-step structure in the Y-Z plane. In these embodiments, compared with the portion 240A, the portion 240B has protruding portions that protrude from sidewalls of the portion 240A in the Y-direction by at least a dimension that is in a range from about 1 nm to about 10 nm.

In some embodiments, an X-direction width of the portion 240B is greater than an X-direction width of the portion 240A, as shown in FIG. 2B. In these embodiments, the source/drain contact 240 including the portions 240A and 240B may have a two-step structure in the X-Z plane. In these embodiments, compared with the portion 240A, the portion 240B has protruding portions that protrude from sidewalls of the portion 240A in the X-direction by at least a dimension that is in a range from about 1 nm to about 10 nm.

Still referring to FIGS. 2A and 2B, the semiconductor device 200 further includes a sidewall dielectric layer 250 formed on sidewalls of the source/drain contact 240, in accordance with some embodiments. In some embodiments, the sidewall dielectric layer 250 separates the source/drain contact 240 from the ILD layer 130, the isolation structures 104, and the substrate 102. Since the sidewall dielectric layer 250 can separate the source/drain contact 240 from other components, the isolation between the source/drain contact 240 and other components can be improved. In some embodiments, at the interface between the source/drain contact 240 and the source/drain feature 118P1, since the sidewall dielectric layer 250 is formed on the sidewalls of the source/drain contact 240, dimensions of the source/drain contact 240 are smaller than dimensions of the source/drain feature 118P1 in the X-direction and the Y-direction. In some embodiments, the sidewall dielectric layer 250 and the source/drain contact 240 collectively constitute a two-step structure in the Y-Z plane and the X-Z plane.

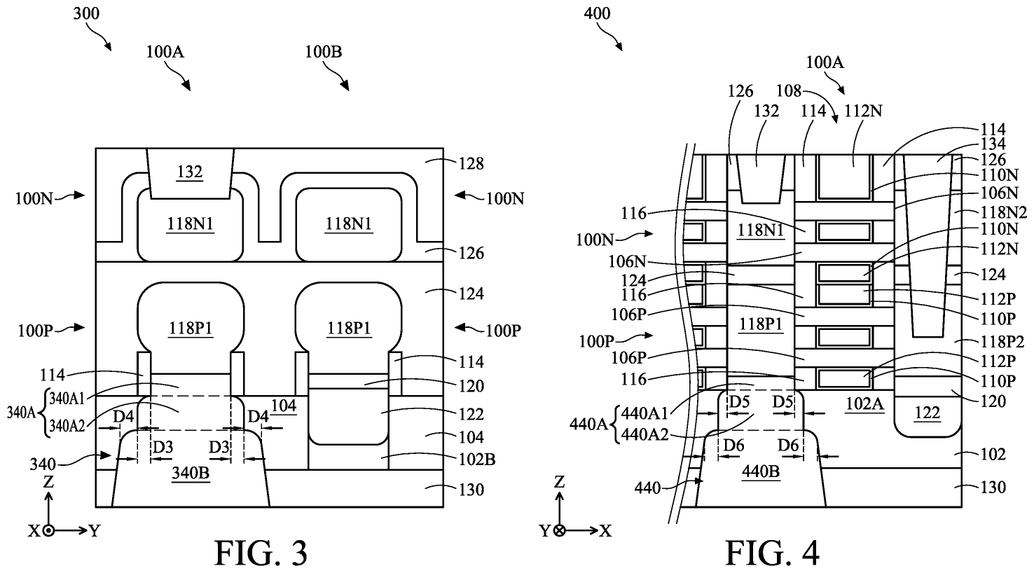

FIG. 3 is a Y-Z cross-sectional view of a semiconductor device 300, in accordance with alternative embodiments of the present disclosure. The semiconductor device 300 shown in FIG. 3 may be similar to the semiconductor device 100 shown in FIGS. 1A and 1B, except the source/drain contact 140 shown in FIGS. 1A and 1B is replaced by a source/drain contact 340 shown in FIG. 3.

Referring to FIG. 3, similar to the source/drain contact 140 shown in FIGS. 1A and 1B, the source/drain contact 340 includes a portion 340A that is in contact with the source/drain feature 118P, and a portion 340B that is below the portion 340A in the Z-direction, in accordance with some embodiments. In some embodiments, the portion 340A includes a sub-portion 340A1 that is in contact with the source/drain feature 118P, and a sub-portion 340A2 that is between the sub-portion 340A1 and the portion 340B. In some embodiments, sub-portion 340A1 is outside the isolation structures 104, and the sub-portion 340A2 is surrounded by the isolation structures 104 in the Y-direction. In some embodiments, a Y-direction width of the sub-portion 340A2 is greater than a Y-direction width of the sub-portion 340A1, as shown in FIG. 3. In these embodiments, compared with the sub-portion 340A1, the sub-portion 340A2 has protruding portions that protrude from sidewalls of the sub-portion 340A1 in the Y-direction by at least a dimension D3. In certain embodiments, the dimension D3 is in a range from about 1 nm to about 10 nm.

In some embodiments, a Y-direction width of the portion 340B is greater than the Y-direction width of the sub-portion 340A2, as shown in FIG. 3. In these embodiments, compared with the sub-portion 340A2, the portion 340B has protruding portions that protrude from sidewalls of the sub-portion 340A2 in the Y-direction by at least a dimension D4. In certain embodiments, the dimension D4 is in a range from about 1 nm to about 10 nm. In these embodiments, the source/drain contact 340 including the sub-portions 340A1 and 340A2 and the portion 340B may have a three-step structure in the Y-Z plane. In some embodiments, in the Y-Z plane, top corners of the sub-portion 340A2 are rounded, and/or top corners of the portion 340B are rounded, as shown in FIG. 3.

FIG. 4 is an X-Z cross-sectional view of a semiconductor device 400, in accordance with alternative embodiments of the present disclosure. The semiconductor device 400 shown in FIG. 4 may be similar to the semiconductor device 100 shown in FIGS. 1A and 1B, except the source/drain contact 140 shown in FIGS. 1A and 1B is replaced by a source/drain contact 440 shown in FIG. 4.

Referring to FIG. 4, similar to the source/drain contact 140 shown in FIGS. 1A and 1B, the source/drain contact 440 includes a portion 440A that is in contact with the source/drain feature 118P, and a portion 440B that is below the portion 440A in the Z-direction, in accordance with some embodiments. In some embodiments, the portion 440A includes a sub-portion 440A1 that is in contact with the source/drain feature 118P, and a sub-portion 440A2 that is between the sub-portion 340A1 and the portion 340B. In some embodiments, sub-portion 440A1 is outside the substrate 102, and the sub-portion 440A2 is surrounded by the substrate 102 in the X-direction. In some embodiments, an X-direction width of the sub-portion 440A2 is greater than an X-direction width of the sub-portion 440A1, as shown in FIG. 4. In these embodiments, compared with the sub-portion 440A1, the sub-portion 440A2 has protruding portions that protrude from sidewalls of the sub-portion 440A1 in the X-direction by at least a dimension D5. In certain embodiments, the dimension D5 is in a range from about 1 nm to about 10 nm.

In some embodiments, an X-direction width of the portion 440B is greater than the X-direction width of the sub-portion 440A2, as shown in FIG. 4. In these embodiments, compared with the sub-portion 440A2, the portion 440B has protruding portions that protrude from sidewalls of the sub-portion 440A2 in the X-direction by at least a dimension D6. In certain embodiments, the dimension D6 is in a range from about 1 nm to about 10 nm. In these embodiments, the source/drain contact 440 including the sub-portions 440A1 and 440A2 and the portion 440B may have a three-step structure in the X-Z plane. In some embodiments, in the X-Z plane, top corners of the sub-portion 440A2 are rounded, and/or top corners of the portion 440B are rounded, as shown in FIG. 4. In some embodiments, the sub-portion 440A1 of the source/drain contact 440 is in contact with the bottommost one of the inner spacers 116.

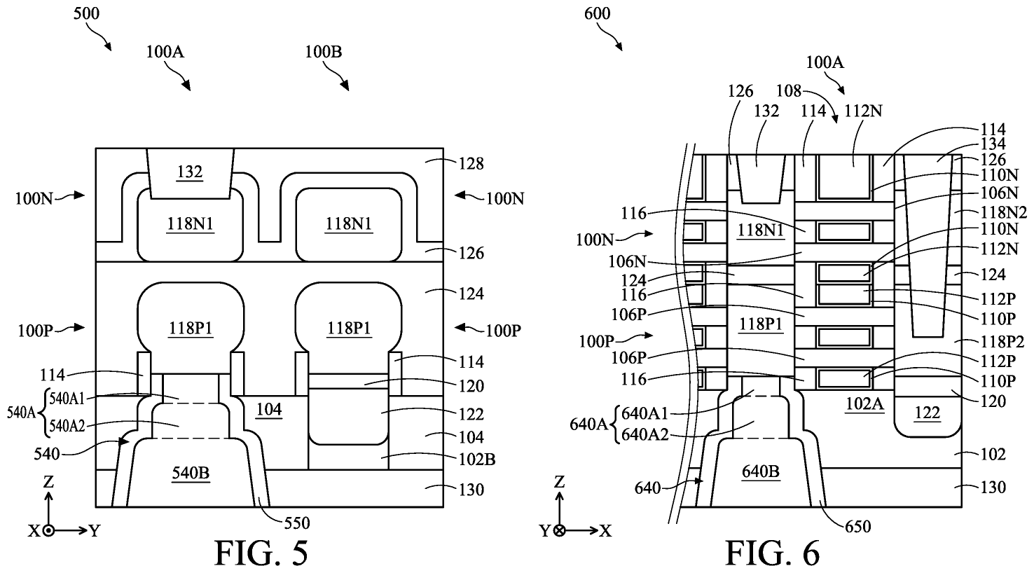

FIG. 5 is a Y-Z cross-sectional view of a semiconductor device 500, in accordance with alternative embodiments of the present disclosure. The semiconductor device 500 shown in FIG. 5 may be similar to the semiconductor device 300 shown in FIG. 3, except the source/drain contact 340 shown in FIG. 3 is replaced by a source/drain contact 540 shown in FIG. 5.

Referring to FIG. 5, similar to the source/drain contact 340 shown in FIG. 3, the source/drain contact 540 includes a portion 540A that is in contact with the source/drain feature 118P, and a portion 540B that is below the portion 540A in the Z-direction, in accordance with some embodiments. In some embodiments, the portion 540A includes a sub-portion 540A1 that is in contact with the source/drain feature 118P, and a sub-portion 540A2 that is between the sub-portion 540A1 and the portion 540B. In some embodiments, a Y-direction width of the sub-portion 540A2 is greater than a Y-direction width of the sub-portion 540A1, as shown in FIG. 5. In these embodiments, compared with the sub-portion 540A1, the sub-portion 540A2 has protruding portions that protrude from sidewalls of the sub-portion 540A1 in the Y-direction by at least a dimension that is in a range from about 1 nm to about 10 nm.

In some embodiments, a Y-direction width of the portion 540B is greater than the Y-direction width of the sub-portion 540A2, as shown in FIG. 5. In these embodiments, compared with the sub-portion 540A2, the portion 540B has protruding portions that protrude from sidewalls of the sub-portion 540A2 in the Y-direction by at least a dimension that is in a range from about 1 nm to about 10 nm. In these embodiments, the source/drain contact 540 including the sub-portions 540A1 and 540A2 and the portion 540B may have a three-step structure in the Y-Z plane. In some embodiments, in the Y-Z plane, top corners of the sub-portion 540A2 are rounded, and/or top corners of the portion 540B are rounded, as shown in FIG. 5.

Still referring to FIG. 5, the semiconductor device 500 further includes a sidewall dielectric layer 550 formed on sidewalls of the source/drain contact 540, in accordance with some embodiments. In some embodiments, the sidewall dielectric layer 550 separates the source/drain contact 540 from the ILD layer 130, the isolation structures 104, and the substrate 102. Since the sidewall dielectric layer 550 can separate the source/drain contact 540 from other components, the isolation between the source/drain contact 540 and other components can be improved.

In some embodiments, at the interface between the source/drain contact 540 and the source/drain feature 118P1, since the sidewall dielectric layer 550 is formed on the sidewalls of the source/drain contact 540, dimensions of the source/drain contact 540 are smaller than dimensions of the source/drain feature 118P1 in the X-direction and the Y-direction. In some embodiments, the sidewall dielectric layer 550 and the source/drain contact 540 collectively constitute a three-step structure in the Y-Z plane.

FIG. 6 is an X-Z cross-sectional view of a semiconductor device 600, in accordance with alternative embodiments of the present disclosure. The semiconductor device 600 shown in FIG. 6 may be similar to the semiconductor device 400 shown in FIG. 4, except the source/drain contact 440 shown in FIG. 4 is replaced by a source/drain contact 640 shown in FIG. 6.

Referring to FIG. 6, similar to the source/drain contact 440 shown in FIG. 4, the source/drain contact 640 includes a portion 640A that is in contact with the source/drain feature 118P, and a portion 640B that is below the portion 640A in the Z-direction, in accordance with some embodiments. In some embodiments, the portion 640A includes a sub-portion 640A1 that is in contact with the source/drain feature 118P, and a sub-portion 640A2 that is between the sub-portion 640A1 and the portion 640B. In some embodiments, an X-direction width of the sub-portion 640A2 is greater than an X-direction width of the sub-portion 640A1, as shown in FIG. 6. In these embodiments, compared with the sub-portion 640A1, the sub-portion 640A2 has protruding portions that protrude from sidewalls of the sub-portion 640A1 in the X-direction by at least a dimension that is in a range from about 1 nm to about 10 nm.

In some embodiments, an X-direction width of the portion 640B is greater than the X-direction width of the sub-portion 640A2, as shown in FIG. 6. In these embodiments, compared with the sub-portion 640A2, the portion 640B has protruding portions that protrude from sidewalls of the sub-portion 640A2 in the X-direction by at least a dimension that is in a range from about 1 nm to about 10 nm. In these embodiments, the source/drain contact 640 including the sub-portions 640A1 and 640A2 and the portion 640B may have a three-step structure in the X-Z plane. In some embodiments, in the X-Z plane, top corners of the sub-portion 640A2 are rounded, and/or top corners of the portion 640B are rounded, as shown in FIG. 6.

Still referring to FIG. 6, the semiconductor device 600 further includes a sidewall dielectric layer 650 formed on sidewalls of the source/drain contact 640, in accordance with some embodiments. In some embodiments, the sidewall dielectric layer 650 separates the source/drain contact 640 from the ILD layer 130, the isolation structures 104, and the substrate 102. Since the sidewall dielectric layer 650 can separate the source/drain contact 640 from other components, the isolation between the source/drain contact 640 and other components can be improved.

In some embodiments, at the interface between the source/drain contact 640 and the source/drain feature 118P1, since the sidewall dielectric layer 650 is formed on the sidewalls of the source/drain contact 640, dimensions of the source/drain contact 640 are smaller than dimensions of the source/drain feature 118P1 in the X-direction and the Y-direction. In some embodiments, the sidewall dielectric layer 650 and the source/drain contact 640 collectively constitute a three-step structure in the X-Z plane.

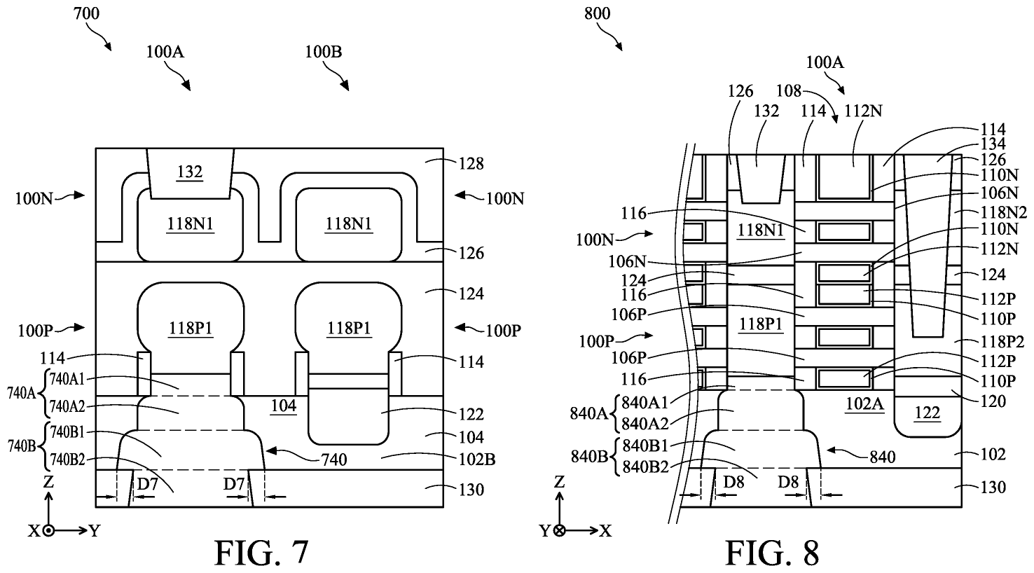

FIG. 7 is a Y-Z cross-sectional view of a semiconductor device 700, in accordance with alternative embodiments of the present disclosure. The semiconductor device 700 shown in FIG. 7 may be similar to the semiconductor device 300 shown in FIG. 3, except the source/drain contact 340 shown in FIG. 3 is replaced by a source/drain contact 740 shown in FIG. 7.

Referring to FIG. 7, similar to the source/drain contact 340 shown in FIG. 3, the source/drain contact 740 includes a portion 740A that is in contact with the source/drain feature 118P, and a portion 740B that is below the portion 740A in the Z-direction, in accordance with some embodiments. In some embodiments, the portion 740A includes a sub-portion 740A1 that is in contact with the source/drain feature 118P, and a sub-portion 740A2 that is below the sub-portion 740A1. In some embodiments, sub-portion 740A1 is outside the isolation structures 104, and the sub-portion 740A2 is surrounded by the isolation structures 104 in the Y-direction. In some embodiments, the portion 740B includes a sub-portion 740B1 that is below and in contact with the sub-portion 740A2, and a sub-portion 740B2 that is below the sub-portion 740B1. In some embodiments, the sub-portion 740B1 is surrounded by the isolation structures 104 in the Y-direction, and the sub-portion 740B2 is surrounded by the ILD layer 130 in the Y-direction

In some embodiments, a Y-direction width of the sub-portion 740A2 is greater than a Y-direction width of the sub-portion 740A1, as shown in FIG. 7. In these embodiments, compared with the sub-portion 740A1, the sub-portion 740A2 has protruding portions that protrude from sidewalls of the sub-portion 740A1 in the Y-direction by at least a dimension that is in a range from about 1 nm to about 10 nm. In some embodiments, a Y-direction width of the sub-portion 740B1 is greater than the Y-direction width of the sub-portion 740A2, as shown in FIG. 7. In these embodiments, compared with the sub-portion 740A2, the sub-portion 740B1 has protruding portions that protrude from sidewalls of the sub-portion 740A2 in the Y-direction by at least a dimension that is in a range from about 1 nm to about 10 nm.

In some embodiments, the sub-portion 740B1 has protruding portions that protrude from sidewalls of the sub-portion 740B2 in the Y-direction. In these embodiments, in each sides in the Y-direction, the bottom surface of the sub-portion 740B 1 protrudes from the top surface of the sub-portion 740B2 by a dimension D7, as shown in FIG. 7. In certain embodiments, the dimension D7 is in a range from about 1 nm to about 10 nm. In these embodiments, the source/drain contact 740 including the sub-portions 740A1, 740A2, 740B1, and 740B2 may have a four-step structure in the Y-Z plane. In some embodiments, in the Y-Z plane, top corners of the sub-portion 740A2 are rounded, and/or top corners of the sub-portion 740B1 are rounded, as shown in FIG. 7. In further embodiments, the semiconductor device 700 may further include a sidewall dielectric layer formed on sidewalls of the source/drain contact 740.

FIG. 8 is an X-Z cross-sectional view of a semiconductor device 800, in accordance with alternative embodiments of the present disclosure. The semiconductor device 800 shown in FIG. 8 may be similar to the semiconductor device 400 shown in FIG. 4, except the source/drain contact 440 shown in FIG. 4 is replaced by a source/drain contact 840 shown in FIG. 8.

Referring to FIG. 8, similar to the source/drain contact 440 shown in FIG. 4, the source/drain contact 840 includes a portion 840A that is in contact with the source/drain feature 118P, and a portion 840B that is below the portion 840A in the Z-direction, in accordance with some embodiments. In some embodiments, the portion 840A includes a sub-portion 840A1 that is in contact with the source/drain feature 118P, and a sub-portion 840A2 that is below the sub-portion 840A1. In some embodiments, sub-portion 840A1 is outside substrate 102, and the sub-portion 840A2 is surrounded by the substrate 102 in the X-direction. In some embodiments, the portion 840B includes a sub-portion 840B1 that is below and in contact with the sub-portion 840A2, and a sub-portion 840B2 that is below the sub-portion 840B1. In some embodiments, the sub-portion 840B1 is surrounded by the substrate 102 in the X-direction, and the sub-portion 840B2 is surrounded by the ILD layer 130 in the X-direction.

In some embodiments, an X-direction width of the sub-portion 840A2 is greater than an X-direction width of the sub-portion 840A1, as shown in FIG. 8. In these embodiments, compared with the sub-portion 840A1, the sub-portion 840A2 has protruding portions that protrude from sidewalls of the sub-portion 840A1 in the X-direction by at least a dimension that is in a range from about 1 nm to about 10 nm. In some embodiments, an X-direction width of the sub-portion 840B1 is greater than the X-direction width of the sub-portion 840A2, as shown in FIG. 8. In these embodiments, compared with the sub-portion 840A2, the sub-portion 840B1 has protruding portions that protrude from sidewalls of the sub-portion 840A2 in the X-direction by at least a dimension that is in a range from about 1 nm to about 10 nm.

In some embodiments, the sub-portion 840B1 has protruding portions that protrude from sidewalls of the sub-portion 840B2 in the X-direction. In these embodiments, in each sides in the X-direction, the bottom surface of the sub-portion 840B 1 protrudes from the top surface of the sub-portion 840B2 by a dimension D8, as shown in FIG. 8. In certain embodiments, the dimension D8 is in a range from about 1 nm to about 10 nm. In these embodiments, the source/drain contact 840 including the sub-portions 840A1, 840A2, 840B1, and 840B2 may have a four-step structure in the X-Z plane. In some embodiments, in the X-Z plane, top corners of the sub-portion 840A2 are rounded, and/or top corners of the sub-portion 840B1 are rounded, as shown in FIG. 8. In further embodiments, the semiconductor device 800 may further include a sidewall dielectric layer formed on sidewalls of the source/drain contact 840.

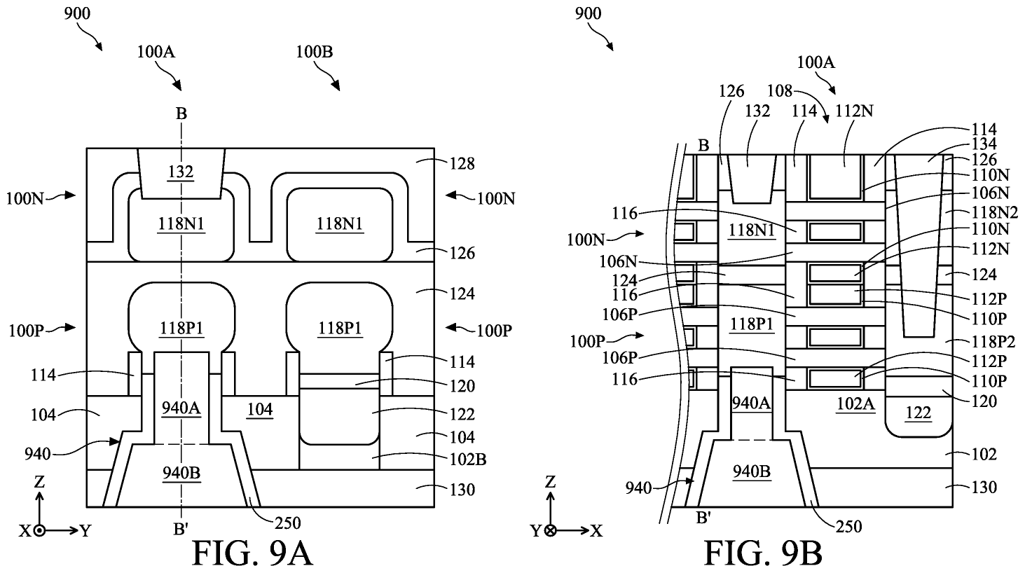

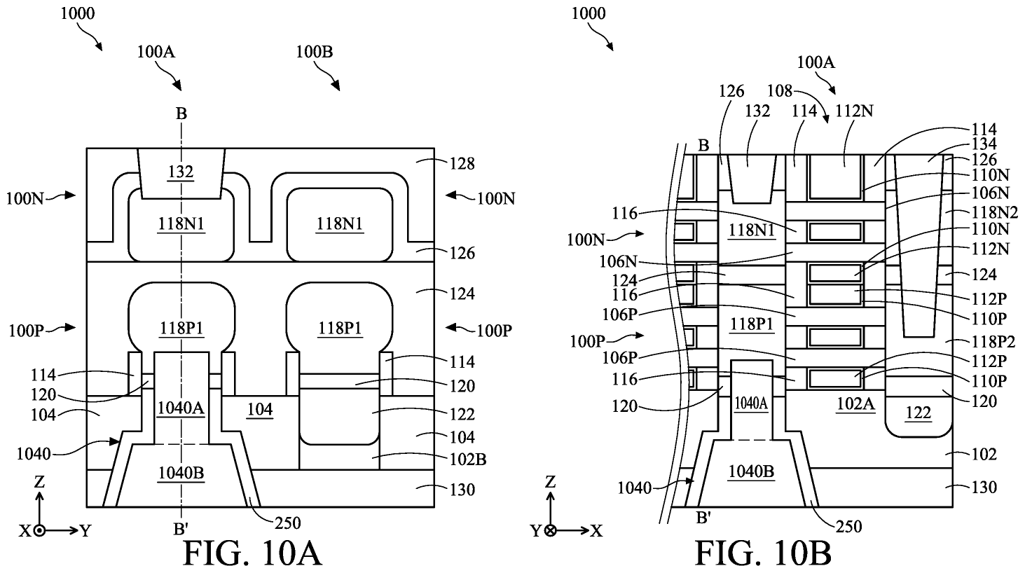

FIG. 9A is a Y-Z cross-sectional view of a semiconductor device 900, in accordance with alternative embodiments of the present disclosure. FIG. 9B is an X-Z cross-sectional view of the semiconductor device 900 along line B-B′ of FIG. 9A, in accordance with alternative embodiments of the present disclosure. The semiconductor device 900 shown in FIGS. 9A and 9B may be similar to the semiconductor device 200 shown in FIGS. 2A and 2B, except the source/drain contact 240 shown in FIGS. 2A and 2B is replaced by a source/drain contact 940 shown in FIGS. 9A and 9B.

Referring to FIGS. 9A and 9B, similar to the source/drain contact 240 shown in FIGS. 2A and 2B, the source/drain contact 940 includes a portion 940A being in contact with the source/drain feature 118P and a portion 940B below the portion 940A in the Z-direction, in accordance with some embodiments. In some embodiments, a Y-direction width of the portion 940B is greater than a Y-direction width of the portion 940A, and an X-direction width of the portion 940B is greater than an X-direction width of the portion 940A, as shown in FIGS. 9A and 9B. In these embodiments, the source/drain contact 940 has a two-step structure in the Y-Z plane and the X-Z plane.

Still referring to FIGS. 9A and 9B, the sidewall dielectric layer 250 is formed on sidewalls of the source/drain contact 940, in accordance with some embodiments. In some embodiments, the portion 940A of the source/drain contact 940 extends beyond the sidewall dielectric layer 250 and into the source/drain feature 118P1 in Z-direction. As shown in FIGS. 9A and 9B, the top portion of the portion 940A is higher than the top portion of the sidewall dielectric layer 250 in Z-direction, and is surrounded by the source/drain feature 118P1. In these embodiments, the sidewall dielectric layer 250 and the source/drain contact 940 collectively constitute a three-step structure.

FIG. 10A is a Y-Z cross-sectional view of a semiconductor device 1000, in accordance with alternative embodiments of the present disclosure. FIG. 10B is an X-Z cross-sectional view of the semiconductor device 1000 along line B-B′ of FIG. 10A, in accordance with alternative embodiments of the present disclosure. The semiconductor device 1000 shown in FIGS. 10A and 10B may be similar to the semiconductor device 200 shown in FIGS. 2A and 2B, except the source/drain contact 240 shown in FIGS. 2A and 2B is replaced by a source/drain contact 1040 shown in FIGS. 10A and 10B.

Referring to FIGS. 10A and 10B, similar to the source/drain contact 240 shown in FIGS. 2A and 2B, the source/drain contact 1040 includes a portion 1040A being in contact with the source/drain feature 118P and a portion 1040B below the portion 1040A in Z-direction, in accordance with some embodiments. In some embodiments, a Y-direction width of the portion 1040B is greater than a Y-direction width of the portion 1040A, and an X-direction width of the portion 1040B is greater than an X-direction width of the portion 1040A, as shown in FIGS. 10A and 10B. In these embodiments, the source/drain contact 1040 has a two-step structure in the Y-Z plane and the X-Z plane.

Still referring to FIGS. 10A and 10B, the sidewall dielectric layer 250 is formed on sidewalls of the source/drain contact 1040, in accordance with some embodiments. In some embodiments, the portion 1040A of the source/drain contact 1040 extends beyond the sidewall dielectric layer 250, through the bottom isolation layer 120, and into the source/drain feature 118P1 in the Z-direction. As shown in FIGS. 10A and 10B, the top portion of the portion 1040A is higher than the top portion of the sidewall dielectric layer 250 in the Z-direction. In these embodiments, the sidewall dielectric layer 250 and the source/drain contact 1040 collectively constitute a three-step structure. In some embodiments, the top portion of the portion 1040A is higher than the top portion of the bottom isolation layer 120 in the Z-direction. In these embodiments, the portion 1040A is partially surrounded by the bottom isolation layer 120. In other embodiments, the top surface of the source/drain contact 1040 is level with or lower than the top surface of the bottom isolation layer 120.

In some aspects, the top portion of backside source/drain contact may extend beyond the sidewall dielectric layer 250/550/650, through the bottom isolation layer 120, and into the source/drain feature 118P in the Z-direction. For example, in the embodiments depicted in FIGS. 5 to 8, the sub-portions 540A1, 640A1, 740A1, and 840A1 may extend beyond the sidewall dielectric layer 550/650, through the bottom isolation layer 120, and into the source/drain feature 118P1 in the Z-direction.

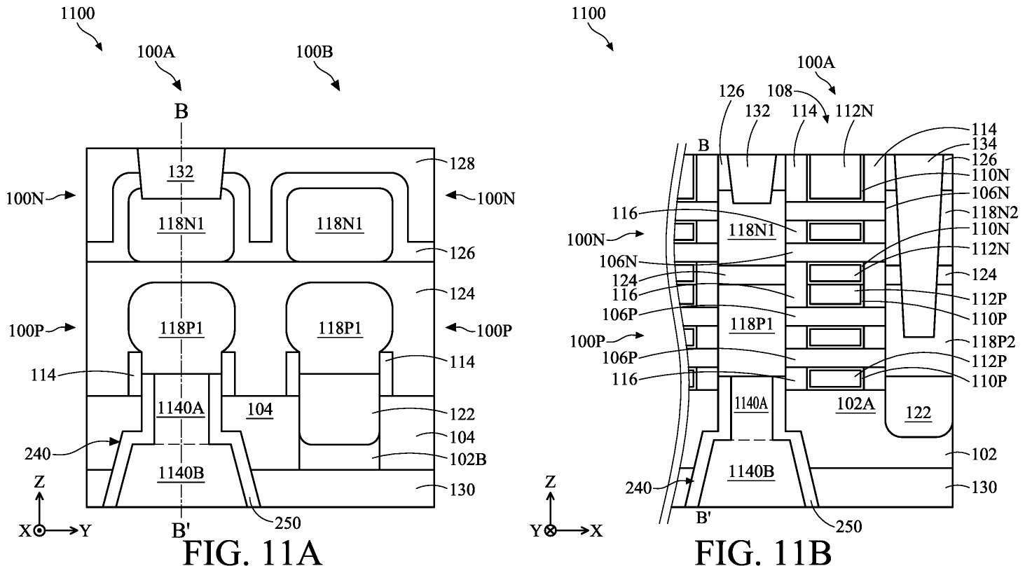

FIG. 11A is a Y-Z cross-sectional view of a semiconductor device 1100, in accordance with alternative embodiments of the present disclosure. FIG. 11B is an X-Z cross-sectional view of the semiconductor device 1100 along line B-B′ of FIG. 11A, in accordance with alternative embodiments of the present disclosure. The semiconductor device 1100 shown in FIGS. 11A and 11B may be similar to the semiconductor device 200 shown in FIGS. 2A and 2B, except the bottom isolation layers 120 shown in FIGS. 2A and 2B are omitted from FIGS. 11A and 11B.

Referring to FIGS. 11A and 11B, compared with the semiconductor device 200 shown in FIGS. 2A and 2B, the bottom isolation layers 120 are omitted from the region below the source/drain features 118P, in accordance with some embodiments. In some embodiments, the SiGe layers 122 are between and in direct contact with source/drain feature 118P1 of the CFET 100B and the substrate 102, and between and in direct contact with source/drain feature 118P2 of the CFET 100A and the substrate 102.

In some aspects, the bottom isolation layers 120 may be omitted from the semiconductor device. For example, in the embodiments shown in FIGS. 1A, 1B, 3-8, 9A, and 9B, the bottom isolation layers 120 may be omitted from the semiconductor devices 100 and 300-900.

In some aspects, the backside source/drain contact in a semiconductor device may have the same multi-step structure in different plane. For example, a backside source/drain contact may have two-step structures, three-step structures, or four-step structures in both the Y-Z plane and the X-Z plane. In other aspects, the backside source/drain contact in a semiconductor device may have different multi-step structures in different planes. For example, a backside source/drain contact may have a two-step structure in the Y-Z plane (e.g., source/drain contacts 140, 240, 940, and 1040) and a three-step structure in X-Z plane (e.g., source/drain contacts 440 and 640). For example, a backside source/drain contact may have a three-step structure in the Y-Z plane (e.g., source/drain contacts 340 and 540) and a two-step structure in the X-Z plane (e.g., source/drain contacts 140, 240, 940 and 1040). For example, a backside source/drain contact may have a two-step structure or a three step structure in the Y-Z plane and a four-step structure in the X-Z plane (e.g., source/drain contact 840), alternatively, a backside source/drain contact may have a four-step structure in the Y-Z plane (e.g., source/drain contact 740) and a two-step structure or a three step structure in the X-Z plane.

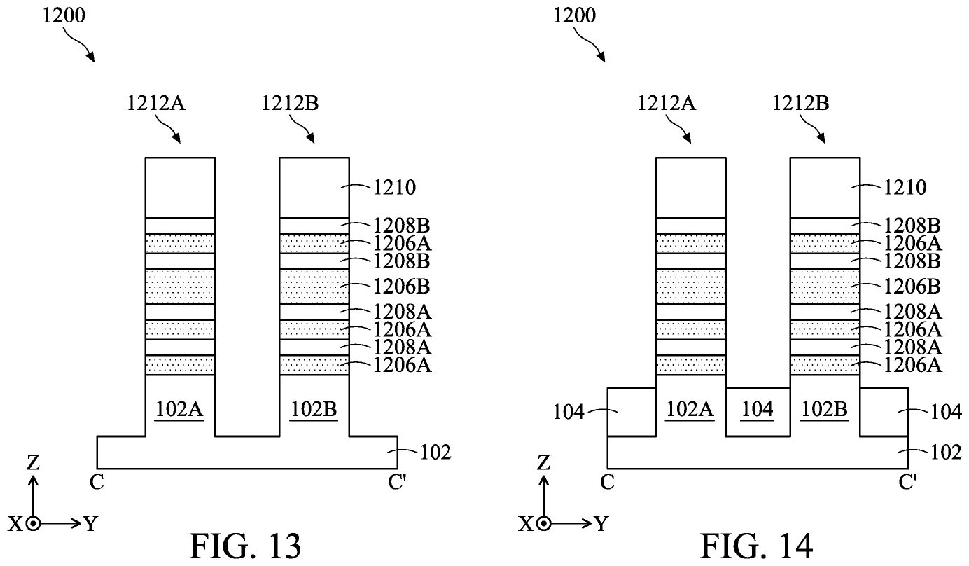

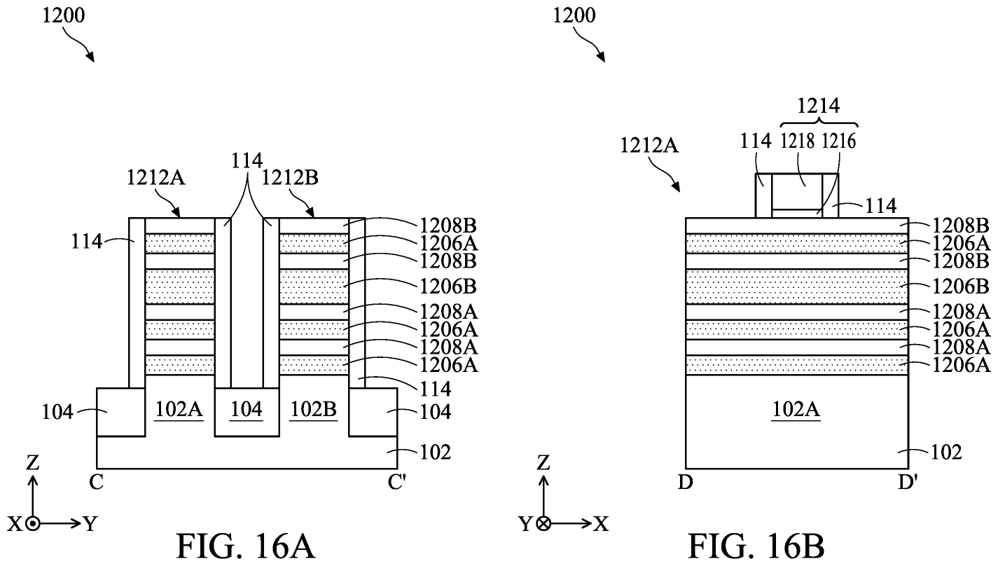

The formation of the semiconductor device (e.g., the semiconductor devices 100-1100) are described in detail in below. The formation of the semiconductor device starts from a workpiece 1200. FIG. 12 is a perspective view of a workpiece 1200 at a fabrication stage, in accordance with some embodiments of the present disclosure. FIGS. 13, 14, 15A, 16A, 17A, 18A, 19A, 20A, 21A, 22A, 23A, 24A, 29A, 30A, 31A, 32A, 33A, 34A, 35, 36, 39, and 40 are Y-Z cross-sectional views of the workpiece 1200 at various fabrication stages along line C-C′ of FIG. 12, in accordance with some embodiments of the present disclosure. FIGS. 16B, 17B, 18B, 19B, 20B, 21B, 22B, 23B, 24B, 25A, 26A, 27A, 28A, 29B, 30B, 31B, 32B, 33B, 34B, 37, 38, 41, and 42 are X-Z cross-sectional views of the workpiece 1200 at various fabrication stages along line D-D′ of FIG. 12, in accordance with some embodiments of the present disclosure. FIGS. 15B, 25B, 26B, 27B, and 28B are Y-Z cross-sectional views of the workpiece 1200 at various fabrication stages along line E-E′ of FIG. 12, in accordance with some embodiments of the present disclosure.

Referring to FIG. 12, the workpiece 1200 is provided. The workpiece 1200 includes a substrate 102 and a stack 1204 over the substrate 102. In some embodiments, the substrate 102 contains a semiconductor material, such as bulk silicon (Si). In some other embodiments, the substrate 102 may include other semiconductors such as Ge, SiGe, or a III-V semiconductor material. Example III-V semiconductor materials may include gallium arsenide (GaAs), indium phosphide (InP), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and indium gallium arsenide (InGaAs). The substrate 102 may also include an insulating layer, such as a silicon oxide layer, to have a silicon-on-insulator (SOI) structure or a germanium-on-insulator (GOI) structure.

In some embodiments, the substrate 102 may include one or more well regions, such as n-type well regions doped with an n-type dopant (e.g., phosphorus (P) or arsenic (As)) or p-type well regions doped with a p-type dopant (e.g., boron (B)), for forming different types of devices. The n-type well regions and the p-type well regions may be formed by using ion implantation or thermal diffusion.

In some embodiments, the stack 1204 includes semiconductor layers 1206 (including semiconductor layers 1206A and a semiconductor layer 1206B) and 1208 (including semiconductor layers 1208A and 1208B), and the semiconductor layers 1206 and 1208 are stacked in an alternating manner in the Z-direction. In some embodiments, the semiconductor layer 1206B is form vertically between a group of semiconductor layers 1208A and a group of semiconductor layers 1208B. In some embodiments, a thickness of the semiconductor layer 1206B is greater than the thickness of the semiconductor layers 1206A, as shown in FIG. 12.

In some embodiments, the thickness of the semiconductor layers 1208A is greater than the semiconductor layers 1208B by a difference in a range from about 0.5 nm to about 5 nm. In other embodiments, the thicknesses of the semiconductor layers 1208A and 1208B are the same. In yet some embodiments, the thickness of the topmost semiconductor layer 1208B is greater than the thickness of the other semiconductor layers 1208B. In some embodiments, the thickness of the bottommost semiconductor layer 1208A is greater than the thickness of the other semiconductor layers 1208A.

The semiconductor layers 1208 may include a semiconductor material, such as silicon, germanium, silicon carbide, silicon phosphide, gallium arsenide, gallium phosphide, indium phosphide, indium arsenide, and/or indium antimonide, SiGe, SiPC, GaAsP, AlInAs, AlGaAs, GaInAs, GaInP, and/or GaInAsP. In some embodiments, the semiconductor layers 1208B include silicon for n-type transistors (i.e., NFETs 100N of the CFETs 100A and 100B). In other embodiments, the semiconductor layers 1208A include silicon germanium for p-type transistors (i.e., PFETs 100P of the CFETs 100A and 100B). In some embodiments, the semiconductor layers 1208 are all made of silicon, and the type of the transistors depend on a work function metal layer wrapping around the nanostructures 106 (which are formed from the semiconductor layers 1208).

The semiconductor layers 1206 and the semiconductor layers 1208 may have different semiconductor compositions. In some embodiments, semiconductor layers 1206 are formed of SiGe and the semiconductor layers 1208 are formed of Si. In these embodiments, the additional germanium content in the semiconductor layers 1206 allow selective removal or recess of the semiconductor layers 1206 without substantial damages to the semiconductor layers 1208, so that the semiconductor layers 1206 are also referred to as sacrificial layers.

In some embodiments, the semiconductor layers 1206 and 1208 are epitaxially grown over or on the substrate 102 using an epitaxial growth such as vapor-phase epitaxy (VPE), metal-organic CVD (MOCVD), molecular beam epitaxy (MBE), although other deposition processes, such as chemical vapor deposition (CVD), low pressure CVD (LPCVD), plasma-enhanced CVD (PECVD), atomic layer deposition (ALD), ultrahigh vacuum CVD (UHVCVD), remote plasma CVD (RPCVD), a combination thereof, or the like, may also be utilized. The semiconductor layers 1206 and 1208 are deposited alternatingly, one-after-another, to form the stack 1204.

The two semiconductor layers 1208A are used for the PFETs 100P of the CFETs 100A and 100B and the two semiconductor layers 1208B are used for the NFETs 100N of the CFETs 100A and 100B. It should be noted that four layers of the semiconductor layers 1206 and four layers of the semiconductor layers 1208 are alternately and vertically arranged (or stacked) as shown in FIG. 12, which are for illustrative purposes only and not intended to be limiting beyond what is specifically recited in the claims. The number of the layers depends on the desired number of channels members for the semiconductor device.

Referring to FIG. 13, the substrate 102 and the stack 1204 are then patterned to form fin structures 1212A and 1212B (may be collectively referred to as fin structures 1212) over the substrate 102. For patterning purposes, the stack 1204 may further include a hard mask layer 1210 over the topmost semiconductor layer. The hard mask layer 1210 may be a single layer structure or a multi-layer structure. In some embodiments, the hard mask layer 1210 is a single layer structure and includes a silicon germanium layer. In some embodiments, the hard mask layer 1210 is a multi-layer structure and includes a silicon nitride layer and a silicon oxide layer over the silicon nitride layer. In other embodiments, the hard mask layer 1210 is a multi-layer structure and includes a silicon germanium layer and a silicon layer over the silicon germanium layer.

As shown in FIG. 13, each of the fin structures 1212 includes a base fin (i.e., the base portions 102A and 102B of the substrate 102 discussed above) formed from the substrate 102 and a stack portion formed from the stack 1204 over the base fin, in accordance with some embodiments. The stack portion of each of the fin structures 1212 includes the semiconductor layers 1206 and 1208 that are alternately stacked in the Z-direction. In some embodiments, the fin structures 1212A and 1212B extend in the X-direction, and are arranged in the Y-direction.

The fin structures 1212 may be patterned using suitable processes including double-patterning or multi-patterning processes. For example, in some embodiments, a material layer is formed over the stack 1204 and patterned using a photolithography process. Spacers are formed alongside the patterned material layer using a self-aligned process. The material layer is then removed, and the remaining spacers, or mandrels, may then be used to pattern the fin structures 1212 by etching the stack 1204 and the substrate 102. The etching process may include dry etching, wet etching, reactive ion etching (RIE), and/or other suitable processes.

Referring to FIG. 14, isolation structures 104 are formed, in accordance with some embodiments. After the fin structures 1212 are formed, the isolation structures 104 are formed over the substrate 102. In some embodiments, the isolation structures 104 extend in the X-direction (not shown) and are arranged with the fin structures 1212 in the Y-direction. In other words, the isolation structures 104 are formed on opposite sides of the fin structures 1212 in the Y-direction. In some aspects, the isolation structures 104 are formed around the fin structures 1212.

The isolation structures 104 may include different structures, such as shallow trench isolation (STI) structures, deep trench isolation (DTI) structures, and/or local oxidation of silicon (LOCOS) structures. In some embodiments, STI structures include a multi-layer structure that fills the trenches, such as a silicon nitride comprising layer disposed over a thermal oxide comprising liner layer. In other embodiments, STI structures include a dielectric layer disposed over a doped liner layer (including, for example, boron silicate glass (BSG) or phosphosilicate glass (PSG)). In certain embodiments, STI structures include a bulk dielectric layer disposed over a liner dielectric layer, wherein the bulk dielectric layer and the liner dielectric layer include materials depending on design requirements.

In some embodiments, a dielectric material for the isolation structures 104 is first deposited over the workpiece 1200. In some embodiments, the dielectric material may include silicon oxide, silicon nitride, silicon oxynitride, FSG, low-k dielectrics, other suitable materials (e.g., including silicon, oxygen, nitrogen, carbon, or other suitable isolation constituent), or combinations thereof. In various embodiments, the dielectric material may be deposited using a deposition process, such as CVD, subatmospheric CVD (SACVD), FCVD, ALD, spin-on coating, or other suitable process. The deposited dielectric material is then thinned and planarized, for example by a CMP process. The planarized dielectric material is further recessed by a dry etching process, a wet etching process, and/or a combination thereof to form the isolation structures 104. In some embodiments, the stack portions of the fin structures 1212 rise above the isolation structures 104 while the base portions 102A and 102B are surrounded by the isolation structures 104, as shown in FIG. 14. In other words, the top surfaces of the substrate 102 is higher than top surfaces of the isolation structures 104.

Referring to FIGS. 15A and 15B, the hard mask layer 1210 is removed and a dummy gate structure 1214 is formed over the fin structures 1212 and the isolation structures 104, in accordance with some embodiments. The dummy gate structure 1214 may be configured to extend along the Y-direction and wrap around top surfaces and side surfaces of the fin structures 1212. In some embodiments, to form the dummy gate structure 1214, a dummy gate dielectric material for a dummy gate dielectric layer 1216 is first formed over fin structures 1212 and over the isolation structures 104. In some embodiments, the dummy gate dielectric material may include, for example, a dielectric material such as a nitride (e.g., silicon nitride, silicon oxynitride), a carbide (e.g., silicon carbide), an oxide (e.g., silicon oxide), or other suitable material.

Then, in some embodiments, a dummy gate electrode material for a dummy gate electrode 1218 is formed over the dummy gate dielectric material. The dummy gate electrode material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or combinations thereof. The dummy gate electrode material and/or the dummy gate dielectric material may be formed by way of a thermal oxidation process and/or a deposition process (e.g., PVD, CVD, PECVD, and ALD).

After the formation of the dummy gate electrode material and the dummy gate dielectric material, photolithography and etching processes may be performed to remove portions of the dummy gate electrode material and the dummy gate dielectric material, thereby forming the dummy gate structure 1214 having the dummy gate electrode 1218 and the dummy gate dielectric layer 1216. The dummy gate structure 1214 may undergo a gate replacement process through subsequent processing to form metal gates, such as a high-k metal gate, as discussed in greater detail below.

Referring to FIGS. 16A and 16B, after forming of the dummy gate structure 1214, the gate spacers 114 are formed on sidewalls of the dummy gate structure 1214, and over the top surfaces and on the sidewalls of the fin structures 1212, in accordance with some embodiments. In some embodiments, the gate spacers 114 are formed on opposite sidewalls of the fin structures 1212, as shown in FIG. 16A, and formed on opposite sidewalls of the dummy gate structures 1214, as shown in FIG. 16B.

The gate spacers 114 may include multiple dielectric materials and be selected from a group consisting of silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, air gap, or a combination thereof. In some embodiments, the gate spacers 114 may include a single layer or a multi-layer structure.

In some embodiments, the gate spacers 114 may be formed by conformally depositing a spacer layer (containing the dielectric material) over the isolation structures 104, the fin structures 1212, and the dummy gate structure 1214, followed by an anisotropic etching process to remove top portions of the spacer layer from the top surfaces of the isolation structures 104, the fin structures 1212, and the dummy gate structure 1214. After the anisotropic etching process, portions of the spacer layer on the sidewall surfaces of the fin structures 1212 and the dummy gate structure 1214 substantially remain and become the gate spacers 114. In some embodiments, the anisotropic etching process is a dry (e.g., plasma) etching process. Additionally or alternatively, the formation of the gate spacers 114 may also involve chemical oxidation, thermal oxidation, CVD, PVD, ALD, HDPCVD, MOCVD, RPCVD, PECVD, LPCVD, ALCVD, APCVD, FCVD, and/or other suitable methods.

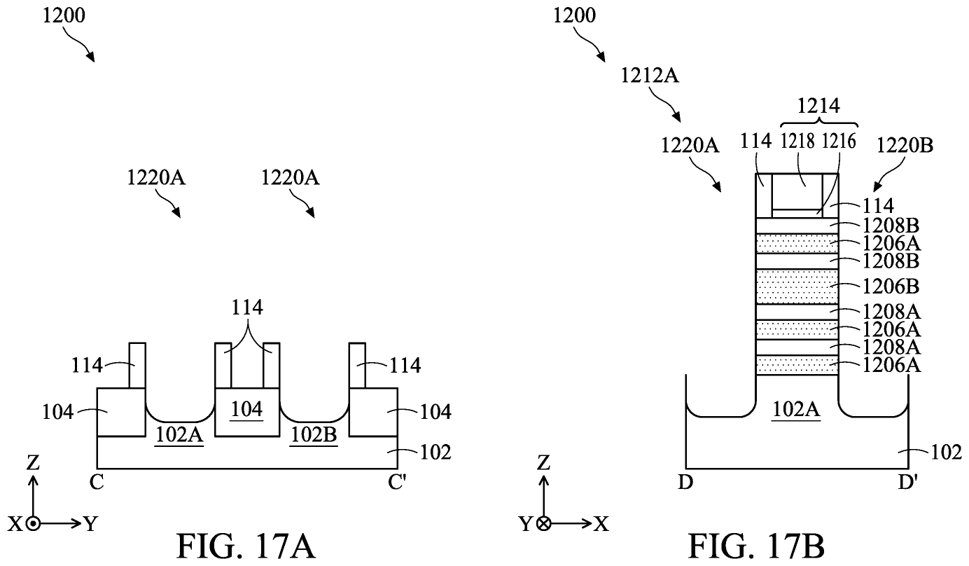

Referring to FIGS. 17A and 17B, the fin structures 1212 are recessed to form source/drain trenches 1220 in the fin structures 1212, in accordance with some embodiments. In some embodiments, in each of the fin structures 1212A and 1212B, the source/drain trenches 1220 include a source/drain trench 1220A and a source/drain trench 1220B that are on opposite sides of the dummy gate structure 1214 in the X-direction. The source/drain trenches 1220 may be formed by performing one or more etching processes to remove portions of the semiconductor layers 1206 and 1208 and the substrate 102 that do not vertically overlap or be covered by the dummy gate structure 1214 and the gate spacers 114. In some embodiments, a single etchant may be used to remove the semiconductor layers 1206 and 1208 and the substrate 102. In other embodiments, multiple etchants may be used to perform the etching process. In some embodiments, portions of the gate spacers 114 on opposite sidewalls of the fin structures 1212 in the Y-direction are removed, as shown in FIG. 17A. In these embodiments, the thicknesses of the gate spacers 114 on the opposite sidewalls of the fin structures 1212 in the Y-direction are reduced.

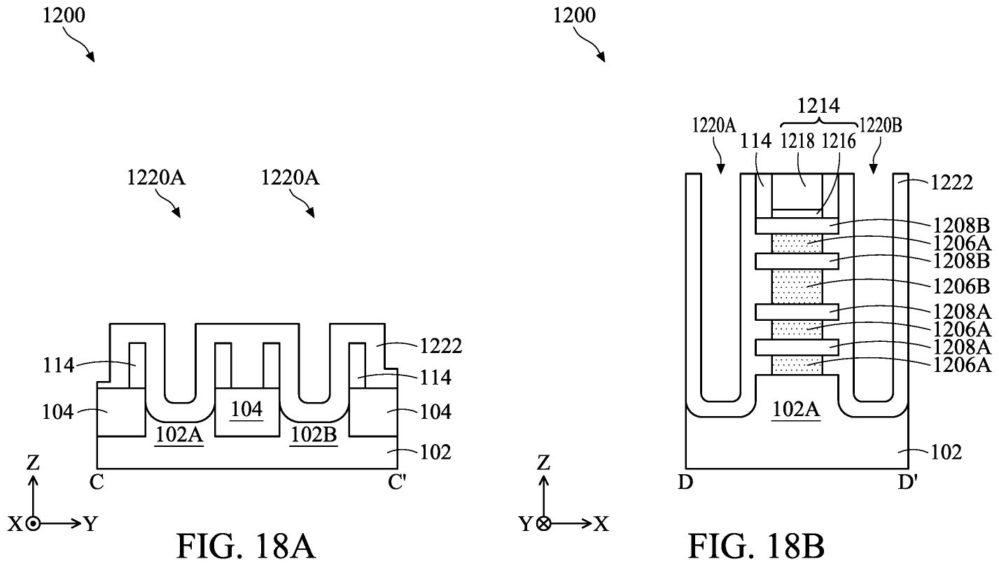

Referring to FIGS. 18A and 18B, the semiconductor layers 1206 (including the semiconductor layers 1206A and 1206B) exposed in the source/drain trenches 1220 are partially recessed through a selective etching process, and the semiconductor layers 1208 are not etched, in accordance with some embodiments. More specifically, the selective etching process is performed that selectively etches the side portions of the semiconductor layers 1206 below the gate spacers 114 through the source/drain trenches 1220, with minimal etching (or substantially no etching) of the semiconductor layers 1208 and the substrate 102. After the selective etching process, inner spacer recesses are vertically formed between the semiconductor layers 1208 as well as between the semiconductor layers 1208 and the substrate 102, below the gate spacers 114. The selective etching process is configured to laterally etch (e.g., along the X-direction) the semiconductor layers 1206 below the gate spacers 114. The selective etching process may be a dry etching process, a wet etching process, other suitable etching process, or combinations thereof.

Still referring to FIGS. 18A and 18B, a spacer layer 1222 is conformally formed into the source/drain trenches 1220 and the inner spacer recesses, in accordance with some embodiments. More specifically, a deposition process is performed to form the spacer layer 1222 into the source/drain trenches 1220 and the inner spacer recesses, such as CVD, PVD, ALD, HDPCVD, MOCVD, RPCVD, PECVD, LPCVD, ALCVD, APCVD, FCVD, other suitable methods, or combinations thereof. The spacer layer 1222 partially (and, in some embodiments, completely) fills the source/drain trenches 1220 and fully fills the inner spacer recesses, as shown in FIG. 18B. The deposition process is configured to ensure that the spacer layer 1222 fills the inner spacer recesses between the semiconductor layers 1208 as well as between the semiconductor layer 1208 and the substrate 102 under the gate spacers 114. Furthermore, the spacer layer 1222 is also conformally formed on the gate spacers 114 and the isolation structures 104, as shown in FIG. 18A.

The spacer layer 1222 includes a material that is different than the material of the semiconductor layers 1208 and the material of the gate spacers 114 to achieve desired etching selectivity during the etching process. In some embodiments, the spacer layer 1222 include a dielectric material that includes silicon, oxygen, carbon, nitrogen, other suitable material, or combinations thereof (e.g., silicon oxide (SiO₂), SiON, SiOC, SiCN, SiOCN). In some embodiments, the spacer layer 1222 include a low-k dielectric material, such as those described herein. In some embodiments, the spacer layer 1222 includes a dielectric material having higher k value (dielectric constant) than the gate spacers 114. In other embodiments, the spacer layer 1222 includes a dielectric material having lower k value than the gate spacers 114.

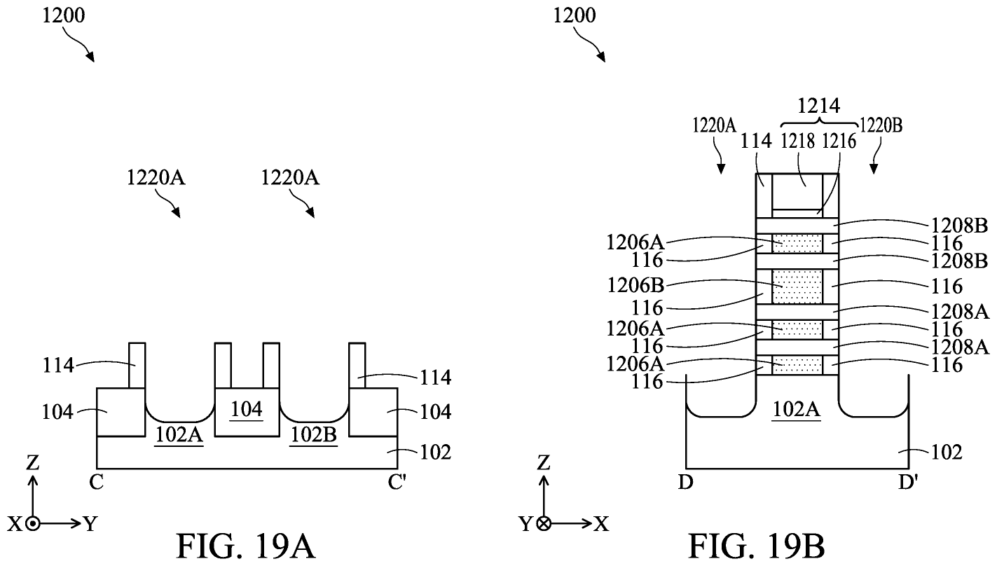

Referring to FIGS. 19A and 19B, the inner spacers 116 are formed to fill the inner spacer recesses between the semiconductor layers 1208 as well as between the semiconductor layer 1208 and the substrate 102, in accordance with some embodiments. More specifically, an etching process is performed to selectively etch the spacer layer 1222 to form the inner spacers 116 with minimal etching (or substantially no etching) of the semiconductor layers 1208, the substrate 102, the dummy gate structure 1214, and the gate spacers 114. The etching process may be an anisotropic etching process, such that portions of the spacer layer 1222 that do not vertically overlap or be covered by the dummy gate structure 1214 and the gate spacers 114 are removed. The spacer layer 1222 on the gate spacers 114 and the isolation structures 104 are removed, as shown in FIG. 19A.

In some embodiments, sidewalls of the inner spacers 116 are aligned to the sidewalls of the gate spacers 114 and the semiconductor layers 1208. Therefore, the inner spacers 116 are formed on opposite sides of the dummy gate structure 1214. Furthermore, the inner spacers 116 are also vertically between the semiconductor layers 1208 as well as between the semiconductor layer 1208 and the substrate 102, in accordance with some embodiments. In some embodiments, the thickness of the gate spacers 114 and the thickness of the inner spacers 116 are the same in the X-direction. In other embodiments, the thickness of the gate spacers 114 is greater than the thickness of the inner spacers 116 in the X-direction for capacitance reduction between source/drain contacts (e.g., the source/drain contacts 118N/118P) and the gate structure (e.g., the gate structure 108).

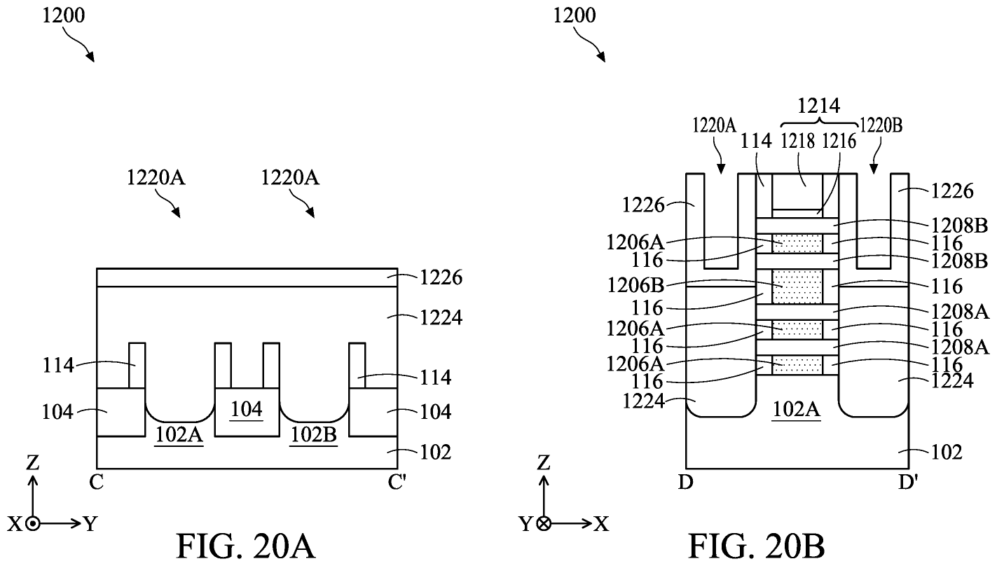

Referring to FIGS. 20A and 20B, polymer layers 1224 and cover spacers 1226 are formed in the source/drain trenches 1220, in accordance with some embodiments. More specifically, the polymer layers 1224 are first formed in lower parts of the source/drain trenches 1220 to cover the top surfaces of the substrate 102 and the sidewalls of the semiconductor layers 1208A (which are used for the PFET of the CFET, such as the PFETs 100P of the CFETs 100A and 100B discussed above) and the inner spacers 116 (which are between the semiconductor layers 1208A) exposed in the source/drain trenches 1220. In some embodiments, top surfaces of the polymer layers 1224 are lower than the semiconductor layers 1208B. In some embodiments, the polymer layers 1224 is also formed on the gate spacers 114 and the isolation structures 104, as shown in FIG. 20A.

After forming the polymer layers 1224, the cover spacers 1226 are conformally formed over the polymer layers 1224 and on the sidewalls of the semiconductor layers 1208B (which are used for the NFET of the CFET, such as the NFETs 100N of the CFETs 100A and 100B discussed above), the gate spacers 114, and the inner spacers 116 (which are between the semiconductor layers 1208B). The polymer layers 1224 may be formed of fluorine-containing polymer and its molecular structure includes silicon (Si), carbon (C), nitrogen (N), or fluorine (F). In some embodiments, the polymer layers 1224 include fluorinated silicone or fluorinated polysilane. In some embodiments, the polymer layers 1224 are spin-on-carbon layers. The polymer layers 1224 may be deposited using CVD, flowable CVD (FCVD), or spin-on coating. The cover spacers 1226 may include aluminum oxide (Al₂O₃).

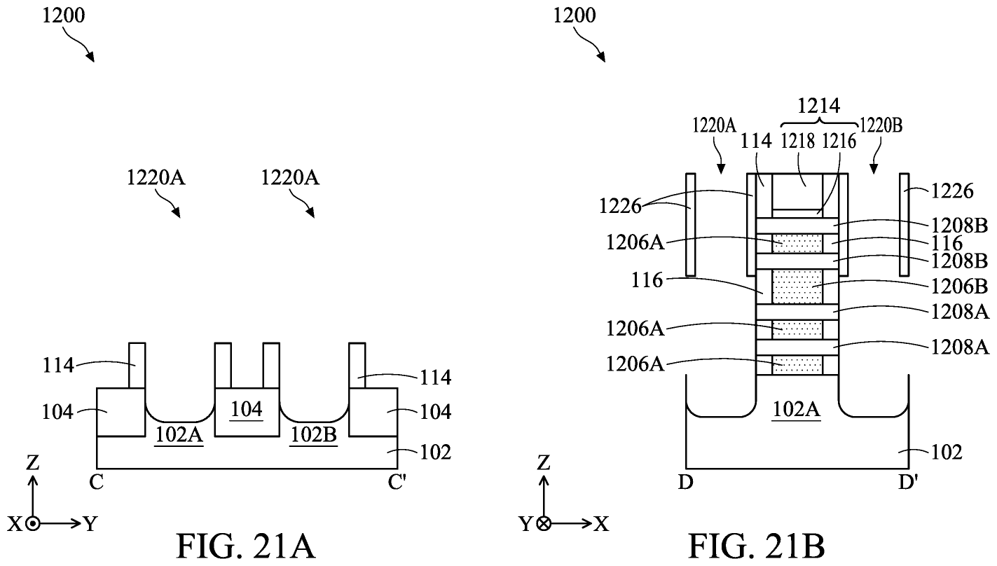

Referring to FIGS. 21A and 21B, the polymer layers 1224 and horizontal portions of the cover spacers 1226 are removed, in accordance with some embodiments. More specifically, an anisotropic etching process is performed to remove the horizontal portions of the cover spacers 1226 to exposed top surfaces of the polymer layers 1224, and then a selective etching process is performed to remove the polymer layers 1224. In some embodiments, vertical portions of the cover spacers 1226 are partially removed or trimmed, but the vertical portions of the cover spacers 1226 still cover the sidewalls of the gate spacers 114 and the semiconductor layers 1208B, as shown in FIG. 21B. The selective etching process is performed that selectively etches the polymer layers 1224 below the cover spacers 1226 through the source/drain trenches 1220, with minimal etching (or substantially no etching) of the semiconductor layers 1208A, the substrate 102, and the inner spacers 116. The selective etching process is a dry etching process, a wet etching process, other suitable etching process, or combinations thereof.

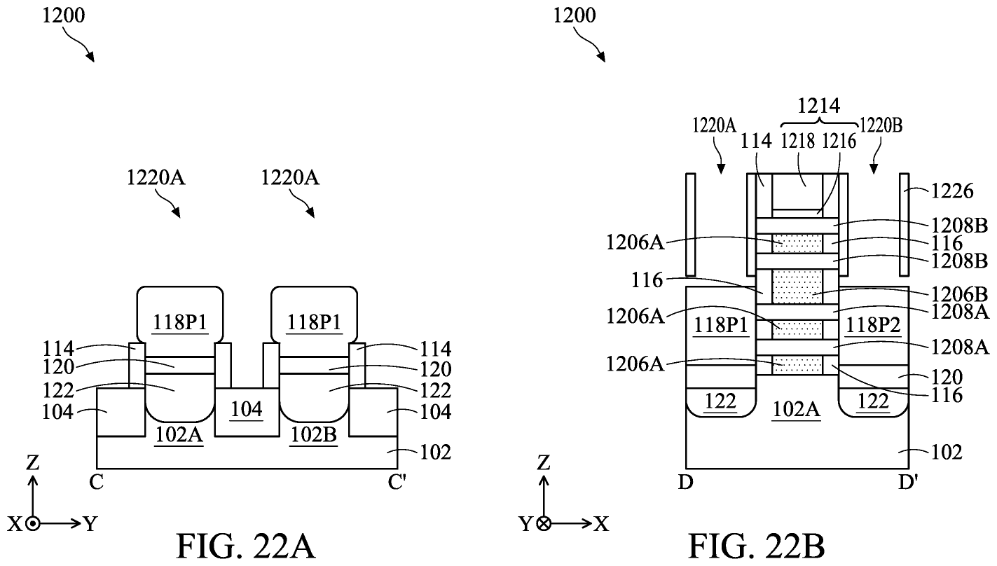

Referring to FIGS. 22A and 22B, after removing the polymer layers 1224, the SiGe layers 122, the bottom isolation layers 120, and the source/drain features 118P are formed in the lower parts of the source/drain trenches 1220 and below the cover spacers 1226, in accordance with some embodiments. In some embodiments, the SiGe layers 122 are formed over the substrate 102 exposed in the source/drain trenches 1220, the bottom isolation layers 120 are formed over the SiGe layers 122, and the source/drain features 118P are formed over the bottom isolation layers 120. In these embodiments, the SiGe layers 122 are vertically between and in contact with the bottom isolation layers 120 and the substrate 102 in the Z-direction, and on opposite sides of the dummy gate structure 1214 in the X-direction. In these embodiments, the bottom isolation layers 120 are vertically between and in contact with the source/drain features 118P and the SiGe layers 122 in the Z-direction and on opposite sides of the dummy gate structure 1214 in the X-direction.

In some embodiments, the SiGe layers 122 are formed in each of the source/drain trenches 1220A and 1220B, as shown in FIGS. 22A and 22B. In some embodiments, a thickness of the SiGe layer 122 in the Z-direction is in a range from about 5 nm to about 50 nm. In some embodiments, the top surfaces of the SiGe layers 122 are higher than the top surfaces of the isolation structures 104. In some embodiments, the SiGe layers 122 may be formed by using epitaxial growth process such as VPE, MOCVD, MBE, although other deposition processes, such as CVD, LPCVD, PECVD, ALD, UHVCVD, RPCVD, a combination thereof, or the like, may also be utilized.

In some embodiments, upper portions of the bottom isolation layers 120 are above and lower portions of the bottom isolation layers 120 are under the topmost surfaces of the substrate 102. In some embodiments, the dielectric material of the bottom isolation layers 120 may include silicon nitride (Si₃N₄), silicon oxide (SiO₂), SiC, SiOC, SiON, SiCN, SiOCN, high-k dielectrics, other suitable materials, or combinations thereof. In some embodiments, the bottom isolation layers 120 may be deposited by CVD, PVD, ALD, HDPCVD, MOCVD, RPCVD, PECVD, LPCVD, ALCVD, APCVD, other suitable methods, or combinations thereof.

In some embodiments, the source/drain features 118P are formed on opposite sides of the dummy gate structure 1214 in X-direction. In some embodiments, source/drain features 118P1 and 118P2 are formed on opposite sides of the dummy gate structure 1214, and in the source/drain trenches 1220A and 1220B respectively, as shown in FIG. 22B. In some embodiments, the source/drain features 118P are connected to and in contact with the semiconductor layers 1208A. In other words, the source/drain features 118P are attached to the opposite sides of a first group of the semiconductor layers 1208 (i.e., the semiconductor layers 1208A). In some embodiments, the semiconductor layers 1208A connect one source/drain feature 118P to another source/drain feature 118P. In some embodiments, the source/drain features 118P may have top surfaces that extend higher than top surfaces of the topmost semiconductor layers 1208A (e.g., in the Z-direction). In other embodiments, the top surfaces of the source/drain features 118P substantially level with the top surfaces of the topmost semiconductor layers 1208A. In some embodiments, the top surfaces of the source/drain features 118P are lower than the bottom surfaces of the cover spacers 1226 and the semiconductor layers 1208B.

In some embodiments, the source/drain features 118P may be formed by using epitaxial growth process such as VPE, MOCVD, MBE, although other deposition processes, such as CVD, LPCVD, PECVD, ALD, UHVCVD, RPCVD, a combination thereof, or the like, may also be utilized. The source/drain features 118P are grown from the semiconductor layers 1208A rather than the semiconductor layers 1208B, the SiGe layers 122, and the substrate 102, it is because that the cover spacers 1226 cover the sidewalls of the semiconductor layers 1208B, and the bottom isolation layers 120 cover the surfaces of the SiGe layers 122 and the substrate 102.

In some embodiments, the source/drain features 118P may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 118P may be doped with p-type dopants (e.g., boron (B), indium (In), other p-type dopant, or a combination thereof) and have a doping concentration in a range from about 1×10¹⁹/cm³ to 6×10²⁰/cm³. In some embodiments, the source/drain features 118P used for the PFETs of the CFETs (e.g., the PFETs 100P of the CFETs 100A and 100B shown in FIGS. 1A to 11B) may be referred to as p-type source/drain features. The source/drain features 118P may be doped in-situ or ex-situ. One or more annealing processes may be performed to activate the dopants in the source/drain features 118P. The annealing processes may include rapid thermal annealing (RTA) and/or laser annealing processes.

In some aspects, the bottom isolation layers 120 may be omitted from the workpiece 1200. In these aspects, the SiGe layers 122 are between and in direct contact with source/drain feature 118P and the substrate 102. When the bottom isolation layers 120 are omitted, the resultant device of the workpiece 1200 may be fabricated to as the semiconductor device 1100 shown in FIGS. 11A and 11B, while the omitting the bottom isolation layers 120 may also adopted to the semiconductor devices 100 and 300-900.

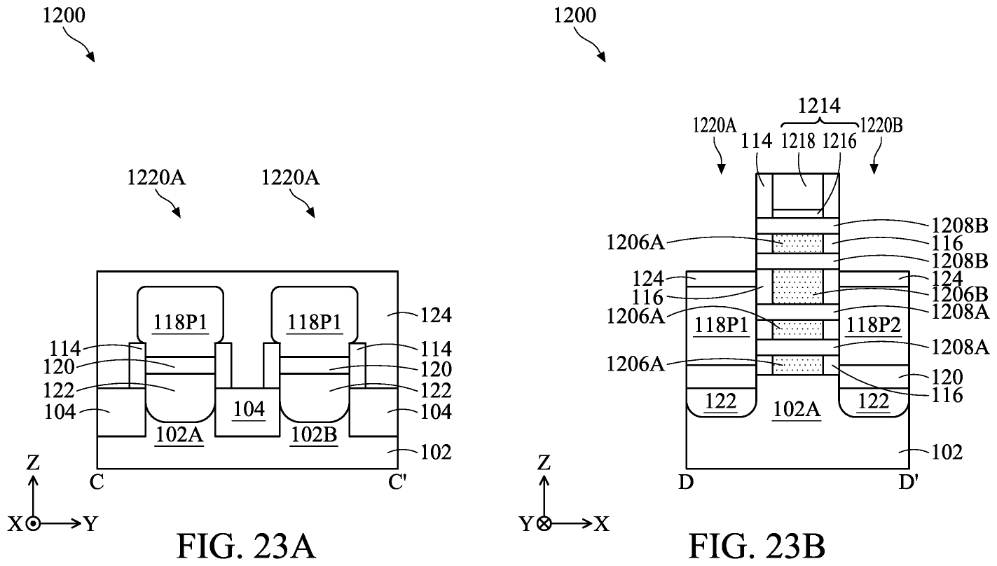

Referring to FIGS. 23A and 23B, the cover spacers 1226 are removed through a selective etching process, and then the ILD layer 124 is formed in the source/drain trenches 1220 and over the substrate 102, the isolation structures 104, and the source/drain features 118P, in accordance with some embodiments. In some embodiments, the selective etching process is performed that selectively etches the cover spacers 1226 over the source/drain features 118P through the source/drain trenches 1220, with minimal etching (or substantially no etching) of the semiconductor layers 1208B, the gate spacers 114, and the inner spacers 116. The selective etching process may be a dry etching process, a wet etching process, other suitable etching process, or combinations thereof.

After removing the cover spacers 1226, the ILD layer 124 is then formed over the substrate 102, the isolation structures 104, and the source/drain features 118P and between the spaces between the source/drain features 118P. In some embodiments, the ILD layer 124 may be formed by CVD, PVD, ALD, HDPCVD, MOCVD, RPCVD, PECVD, LPCVD, ALCVD, APCVD, FCVD, or other suitable methods. Then, the ILD layer 124 over the source/drain features 118P are recessed by performing one or more photolithography and etching processes, so that the sidewalls of the semiconductor layers 1208B over the source/drain features 118P are exposed.

In some embodiments, the ILD layer 124 may include tetraethylorthosilicate (TEOS) formed oxide, un-doped silicate glass, or doped silicon oxide such as borophosphosilicate glass (BPSG), fluoride-doped silica glass (FSG), PSG, BSG, low-k dielectric materials, other suitable dielectric materials, or combinations thereof. Exemplary low-k dielectric materials include carbon doped silicon oxide, Black Diamond® (Applied Materials of Santa Clara, California), xerogel, aerogel, amorphous fluorinated carbon, parylene, BCB-based dielectric material, SiLK (Dow Chemical, Midland, Michigan), polyimide, other low-k dielectric materials, or combinations thereof.

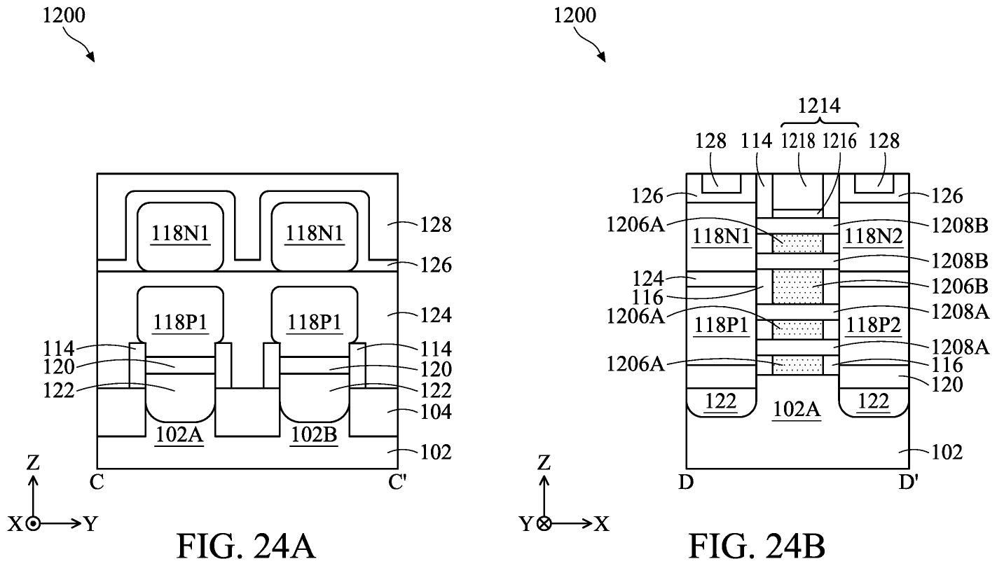

Referring to FIGS. 24A and 24B, the source/drain features 118N are formed in the source/drain trenches 1220, in accordance with some embodiments. In some embodiments, the source/drain features 118N are formed over the ILD layer 124 in the source/drain trenches 1220. The source/drain features 118N are also formed on opposite sides of the dummy gate structure 1214 in the X-direction. In some embodiments, source/drain features 118N1 and 118N2 are formed on opposite sides of the dummy gate structure 1214, and over the source/drain features 118P1 and 118P2 respectively, as shown in FIG. 24B. In some embodiments, the source/drain features 118N are connected to and in contact with the semiconductor layers 1208B. In other words, the source/drain features 118N are attached to the opposite sides of a second group of the semiconductor layers 1208 (i.e., the semiconductor layers 1208B). In some embodiments, the semiconductor layers 1208B connect one source/drain feature 118N to another source/drain feature 118N.

In some embodiments, the source/drain features 118N may have top surfaces that extend higher than top surfaces of the topmost semiconductor layers 1208B (e.g., in the Z-direction). In other embodiments, the top surfaces of the source/drain features 118N are substantially level with the top surfaces of the topmost semiconductor layers 1208B. In some embodiments, the bottom surfaces of the source/drain features 118N are lower than bottom surfaces of the bottommost semiconductor layers 1208B. In other embodiments, the bottom surfaces of the source/drain features 118N are substantially level with the bottom surfaces of the bottommost semiconductor layers 1208B.

In some embodiments, the source/drain features 118N may be formed by using epitaxial growth process such as VPE, MOCVD, MBE, although other deposition processes, such as CVD, LPCVD, PECVD, ALD, UHVCVD, RPCVD, a combination thereof, or the like, may also be utilized. The source/drain features 118N are grown from the semiconductor layers 1208B.

In some embodiments, the source/drain features 118N may include epitaxially-grown material selected from a group consisting of SiP, SiC, SiPC, SiAs, Si, or a combination thereof. In some embodiments, the epitaxially-grown material of the source/drain features 118N may be doped with n-type dopants (e.g., phosphorus (P), arsenic (As), other n-type dopant, or a combination thereof) and have a doping concentration in a range from about 2×10¹⁹/cm³ to 3×10²¹/cm³. In some embodiments, the source/drain features 118N used for the NFETs of the CFETs (e.g., the NFETs 100N of the CFETs 100A and 100B shown in FIGS. 1A to 11B) may be referred to as n-type source/drain features. The source/drain features 118N may be doped in-situ or ex-situ. One or more annealing processes may be performed to activate the dopants in the source/drain features 118N. The annealing processes may include RTA and/or laser annealing processes.

Still referring to FIGS. 24A and 24B, the CESLs 126 are formed over the source/drain features 118N and the ILD layer 124, and the ILD layer 128 is formed over the CESLs 126 to fill the space between the source/drain features 118N, in accordance with some embodiments. In some embodiments, the CESLs 126 are conformally formed on the sidewalls of the gate spacers 114. In some embodiments, the CESLs 126 are also conformally formed on the top surfaces and the sidewalls of the source/drain features 118N. In some embodiments, the CESLs 126 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable materials. The CESLs 126 may be formed by CVD, PVD, ALD, HDPCVD, MOCVD, RPCVD, PECVD, LPCVD, ALCVD, APCVD, FCVD, or other suitable methods.

The ILD layer 128 is formed over and between the CESLs 126 to fill the space between the CESLs 126 and in the source/drain trenches 1220. In some embodiments, the ILD layer 128 includes a material that is different than the CESLs 126. In some embodiments, the ILD layer 128 may include TEOS formed oxide, un-doped silicate glass, or doped silicon oxide such as BPSG, FSG, PSG, BSG, low-k dielectric materials, other suitable dielectric materials, or combinations thereof. The ILD layer 128 may be formed by CVD, PVD, ALD, HDPCVD, MOCVD, RPCVD, PECVD, LPCVD, ALCVD, APCVD, FCVD, or other suitable methods. After forming the CESLs 126 and the ILD layer 128, a CMP process is performed to reduce heights of the CESLs 126 and the ILD layer 128 until top surface of the dummy gate electrode 1218 of the dummy gate structure 1214 is exposed.

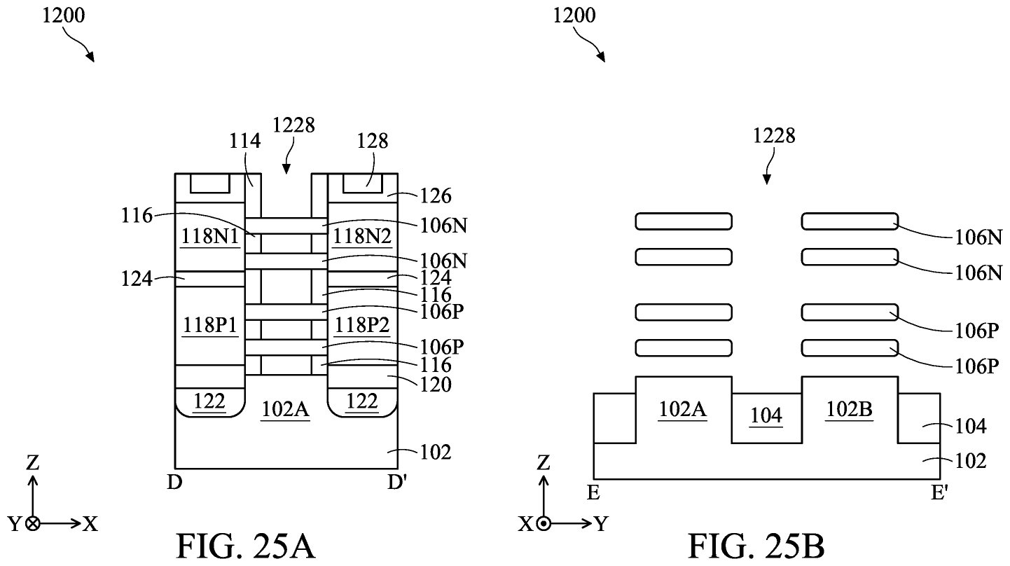

Referring to FIGS. 25A and 25B, the dummy gate structure 1214 are selectively removed through any suitable photolithography and etching processes, in accordance with some embodiments. In some embodiments, the photolithography process may include forming a photoresist layer (resist), exposing the resist to a pattern, performing a post-exposure bake process, and developing the resist to form a masking element, which exposes a region including the dummy gate structure 1214. Then, the dummy gate structure 1214 is selectively etched through the masking element. The gate spacers 114 may be used as the masking element or a part thereof. Etch selectivity may be achieved by selecting appropriate etching chemicals, and the dummy gate structure 1214 may be removed without substantially affecting the CESLs 126 and the ILD layer 128. The removal of the dummy gate structure 1214 creates a gate trench 1228. The gate trench 1228 exposes the top surfaces of the topmost semiconductor layers 1208B that underlie the dummy gate structure 1214.

Still referring to FIGS. 25A and 25B, the semiconductor layers 1206 are selectively removed through the gate trench 1228, using a wet or dry etching process for example, in accordance with some embodiments. After the semiconductor layers 1206 are selectively removed, the semiconductor layers 1208A and 1208B are exposed in the gate trench 1228 to form nanostructures 106P and 106N stacked on top of each other. Specifically, the nanostructures 106P (the semiconductor layers 1208A) are stacked vertically in the Z-direction, and the nanostructures 106N (the semiconductor layers 1208B) are directly over the nanostructures 106P and are stacked vertically in the Z-direction. This process may be referred to as a wire release process, a nanowire release process, a nanosheet release process, a nanowire formation process, a nanosheet formation process, or a wire formation process.

In some embodiments, the thicknesses of nanostructures 106 in the NFET and the PFET (e.g., the NFETs 100N and the PFETs 100P of the CFETs 100A and 100B shown in FIGS. 1A to 11B) in the Z-direction are different. For example, a thickness of the nanostructure 106P may be greater than a thickness of the nanostructure 106N in the Z-direction, alternatively, the thickness of the nanostructure 106P may be smaller than that of the nanostructure 106N in the Z-direction. In some embodiments, the difference between the thicknesses of the nanostructure 106P and the nanostructure 106N is in a range from about 0.5 nm to about 5 nm.

In some embodiments, a pitch between the nanostructures 106P (i.e., the distance from a top surface of the lower nanostructure 106P to a bottom surface of the upper nanostructure 106P) is different from a pitch between the nanostructures 106N (i.e., the distance from a top surface of the lower nanostructure 106N to a bottom surface of the upper nanostructure 106N). In some embodiments, the difference between the pitch of the nanostructures 106P and the pitch of the nanostructures 106N is in a range from about 0.5 nm to about 5 nm. In some embodiments, the length of the nanostructures 106P is greater than the length of the nanostructures 106N in the X-direction. In some embodiments, the difference between the length of the nanostructures 106P and the length of the nanostructures 106N is in a range from about 0.5 nm to about 5 nm.

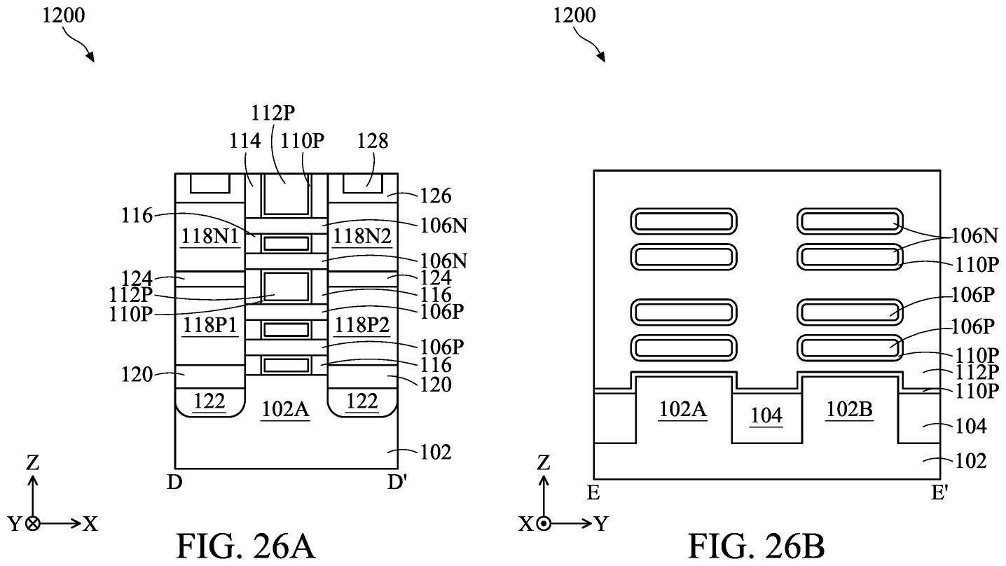

Referring to FIGS. 26A and 26B, the gate dielectric layer 110P and the gate electrode layer 112P are formed in the gate trench 1228 to wrap around each of the nanostructures 106P and 106N (the semiconductor layers 1208A and 1208B), in accordance with some embodiments. In some embodiments, the gate dielectric layer 110P is wrapped around each of the nanostructures 106P and 106N, and the gate electrode layer 112P is wrapped around the gate dielectric layer 110P and each of the nanostructures 106P and 106N. Additionally, the gate dielectric layer 110P is also formed on the sidewalls of the inner spacers 116 and the gate spacers 114 (shown in FIG. 26A), as well as over the top surfaces of the substrate 102 and the isolation structures 104 (shown in FIG. 26B).

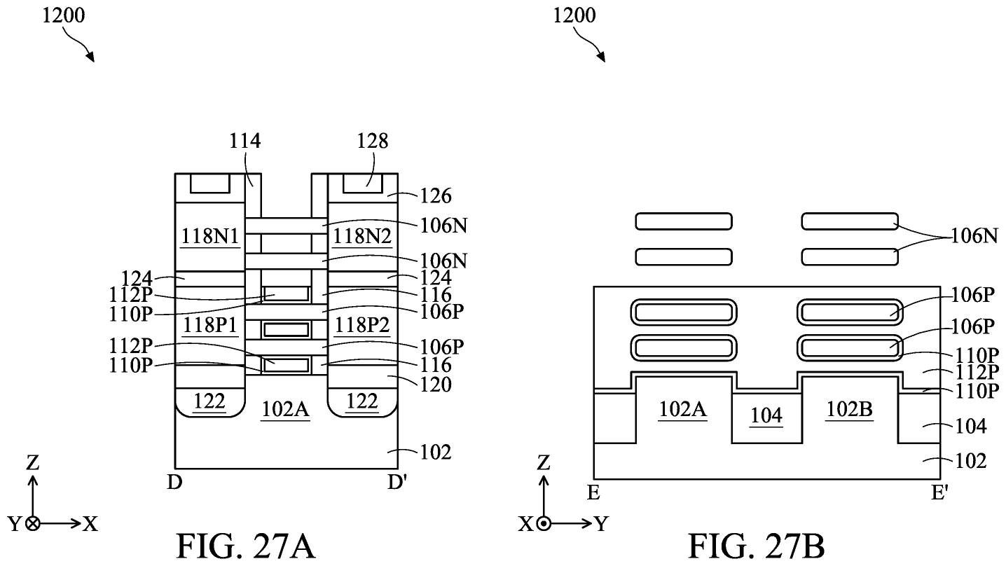

Referring to FIGS. 27A and 27B, the gate dielectric layer 110P and the gate electrode layer 112P in the gate trench 1228 are etched back to expose the nanostructures 106N (the semiconductor layers 1208B), in accordance with some embodiments. In some embodiments, portions of the gate dielectric layer 110P and gate electrode layer 112P that are wrapped around the nanostructures 106N are removed by one or more etching processes. The etching processes may be selective etching processes that selectively etch the gate dielectric layer 110P and the gate electrode layer 112P, with minimal etching (or substantially no etching) of the nanostructures 106N, the gate spacers 114, and the inner spacers 116. The selective etching process may be a dry etching process, a wet etching process, other suitable etching process, or combinations thereof. As shown in FIGS. 27A, after the etching processes, a top surface of the gate electrode layer 112P is lower than the bottommost surfaces of the nanostructures 106N, in accordance with some embodiments.

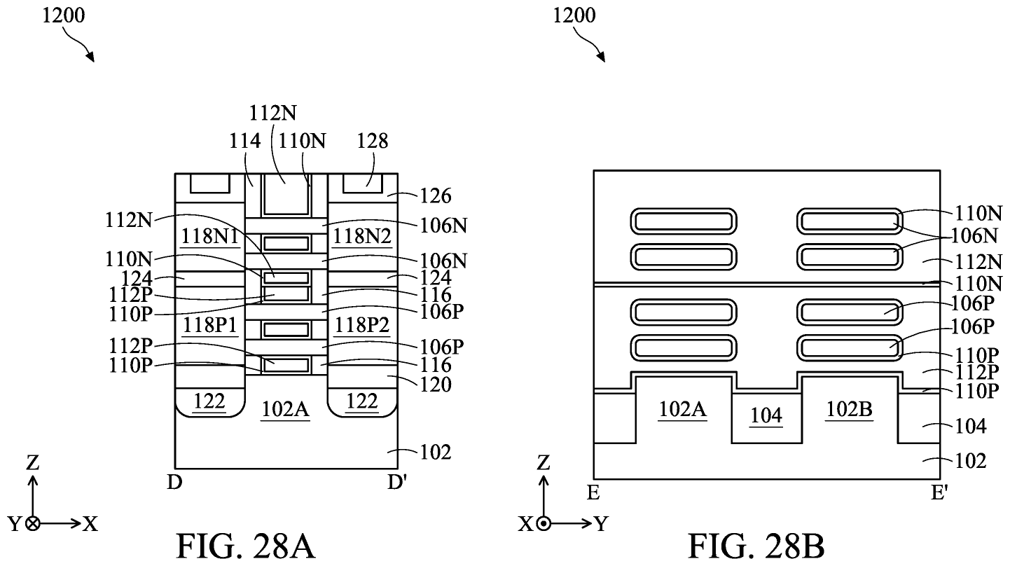

Referring to FIGS. 28A and 28B, the gate dielectric layer 110N and the gate electrode layer 112N are formed in the gate trench 1228 and over the gate dielectric layer 110P and the gate electrode layer 112P to wrap around the nanostructures 106N (the semiconductor layers 1208B), in accordance with some embodiments. In some embodiments, the gate dielectric layer 110N wraps around each of the nanostructures 106N, and the gate electrode layer 112N wraps around the gate dielectric layer 110N and each of the nanostructures 106N. Additionally, the gate dielectric layer 110N is also formed on the sidewalls of the inner spacers 116 and the gate spacers 114 (shown in FIG. 28A), as well as over the top surface of the gate electrode layer 112P (shown in FIG. 28B). In some embodiments, the gate dielectric layer 110N is further in contact with the gate dielectric layer 110P, as shown in FIG. 28A. Therefore, the gate dielectric layer 110P, the gate electrode layer 112P, the gate dielectric layer 110N, and the gate electrode layer 112N may be together referred to as the gate structure 108 to replace the dummy gate structure 1214.

In some embodiments, the gate dielectric layers 110P and 110N may include oxide with nitrogen doped dielectric material (initial layer) combined with metal content high-k dielectric material (e.g., k value (dielectric constant)>7.9). For example, the gate dielectric layers 110P and 110N may include hafnium oxide (HfO₂), which has a dielectric constant in a range from about 18 to about 40. Alternatively, the gate dielectric layers 110P and 110N may include other high-k dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr)TiO₃ (BST), Al₂O₃, Si₃N₄, oxynitrides (SiON), other suitable materials, or combinations thereof. The gate dielectric layers 110P and 110N may be formed by chemical oxidation, thermal oxidation, CVD, physical vapor deposition (PVD), ALD, high-density plasma CVD (HDPCVD), MOCVD, RPCVD, PECVD, LPCVD, atomic layer CVD (ALCVD), atmospheric pressure CVD (APCVD), flowable CVD (FCVD), other suitable methods, or combinations thereof.

In some embodiments, the gate electrode layer 112P may include one or more p-type work function metal layers for PFETs 100P, and the gate electrode layer 112N may include one or more n-type work function metal layers for NFETs 100N. In other embodiments, the gate electrode layer 112P and the gate electrode layer 112N may include the same work function metal layer.

In some embodiments, the n-type and p-type work function metal layers may include a material such as such as W, Al, Cu, TiN, Ti, TiAlN, TiAl, Pt, Ta, TaN, Co, Ni, TaC, TaCN, TaSiN, TaSi₂, NiSi₂, Mn, Zr, ZrSi₂, Ru, AlCu, Mo, MoSi₂, WN, other suitable work function materials, or combinations thereof. In some embodiments, the n-type and p-type work function metal layers may be deposited utilizing CVD, PVD, ALD, HDPCVD, MOCVD, RPCVD, PECVD, LPCVD, ALCVD, APCVD, FCVD, or the like. However, any suitable materials and processes may be utilized to form the n-type work function metal layer and the p-type work function metal layer.

In some embodiments, each of the gate electrode layers 112P and 112N may include a single layer or alternatively a multi-layer structure. In some embodiments, each of the gate electrode layers 112P and 112N may include a capping layer, a barrier layer, and a fill material (not shown). The capping layer may be formed adjacent to the gate dielectric layers 110P and 110N, and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

The barrier layer may be formed adjacent to the capping layer, and may be formed of a different material than the capping layer. For example, the barrier layer may be formed of one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like.

In some embodiments, the fill material may include a suitable conductive material, such as Al, W, and/or Cu. In some embodiments, the capping layer, the barrier layer, and the fill material may be deposited using a deposition process such as CVD, PVD, ALD, HDPCVD, MOCVD, RPCVD, PECVD, LPCVD, ALCVD, APCVD, FCVD, or the like, although any suitable deposition process may be used.

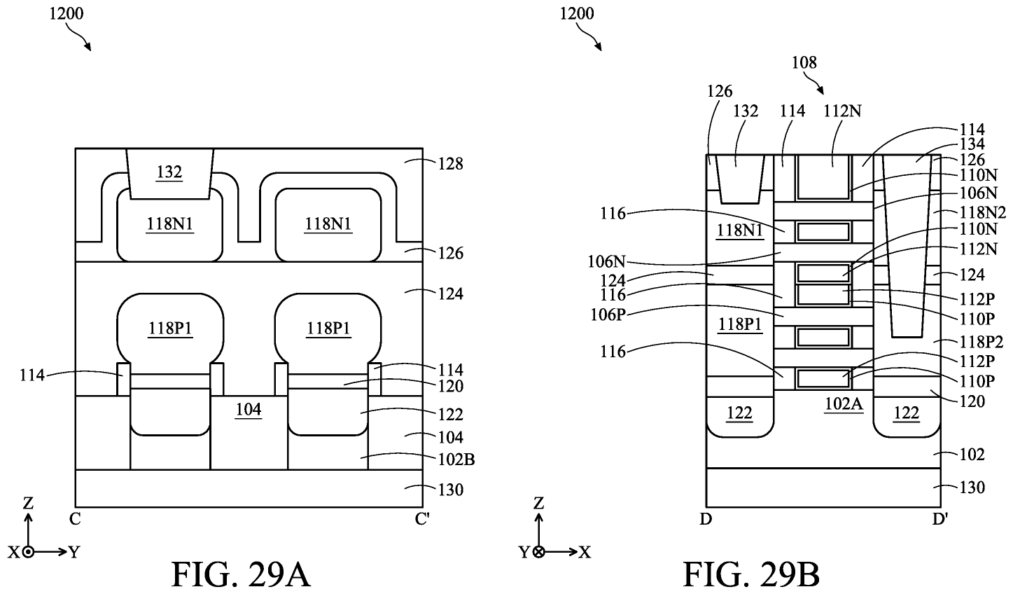

Referring to FIGS. 29A and 29B, the frontside interconnection structure is formed on the frontside of the workpiece 1200, for example, the source/drain contacts 132 and 134 are formed over the source/drain features, in accordance with some embodiments. In some embodiments, the source/drain contact 132 is formed to pass through the ILD layer 128, the CESLs 126, and portions of the source/drain features 118N, so as to contact the source/drain features 118N. In some embodiments, the source/drain contact 132 is in contact with and electrically connected to the source/drain feature 118N1 of the CFET 100A. In some embodiments, the source/drain contact 134 is formed to pass through the ILD layer 128, the CESLs 126, the source/drain features 118N, the ILD layer 124, and portions of the source/drain features 118P, so as to contact both of the source/drain features 118N and 118P. In some embodiments, the source/drain contact 134 is in contact with and electrically connected to the source/drain feature 118N2 and the source/drain feature 118P2 of the CFET 100A.

The formation of the source/drain contact 132 may include forming a contact opening passing through the ILD layer 128 and the CESLs 126 and partially extending into the source/drain feature 118N, so as to expose the source/drain feature 118N. Then, a conductive material of the source/drain contact 132 may be deposited in the contact opening by a deposition process to form the source/drain contact 132. The formation of the source/drain contact 134 may include forming a contact trench passing through the ILD layer 128, the CESLs 126, the source/drain feature 118N, and the ILD layer 124 and partially extending into the source/drain feature 118P, so as to expose the source/drain features 118N and 118P. Then, a conductive material of the source/drain contact 134 may be deposited in the contact trench by a deposition process to form the source/drain contact 134.

The source/drain contacts 132 and 134 may each include a conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, PVD, ALD, HDPCVD, MOCVD, RPCVD, PECVD, LPCVD, ALCVD, APCVD, FCVD, electroplating, electroless plating, or the like. However, any suitable materials and processes may be utilized to form source/drain contacts 132 and 134. In some embodiments, the source/drain contacts 132 and 134 may each include a single conductive material layer or multiple conductive layers.

Still referring to FIGS. 29A and 29B, a portion of the substrate 102 is removed from the backside of the workpiece 1200, and the ILD layer 130 is formed on backside surface of the substrate 102, in accordance with some embodiments. In other words, the substrate is thinned and the ILD layer 130 is formed under and in contact with the thinned substrate 102. Before thinning the substrate 102 and forming the ILD layer 130, the workpiece 1200 may be flipped. For the purpose of simplicity, the sequent figures are shown without being flipped. In some embodiments, a carrier wafer may be bonded to the frontside of the workpiece 1200 before flipping. In some embodiments, the substrate 102 is thinned (or partially removed) by a selective etching process or a CMP process.

After thinning the substrate 102, the ILD layer 130 may be formed under the thinned substrate 102, as shown in FIGS. 29A and 29B. In some embodiments, the ILD layer 130 may include TEOS formed oxide, un-doped silicate glass, or doped silicon oxide such as BPSG, FSG, PSG, BSG, low-k dielectric materials, other suitable dielectric materials, or combinations thereof. The ILD layer 130 may be formed by CVD, PVD, ALD, HDPCVD, MOCVD, RPCVD, PECVD, LPCVD, ALCVD, APCVD, FCVD, or other suitable methods.

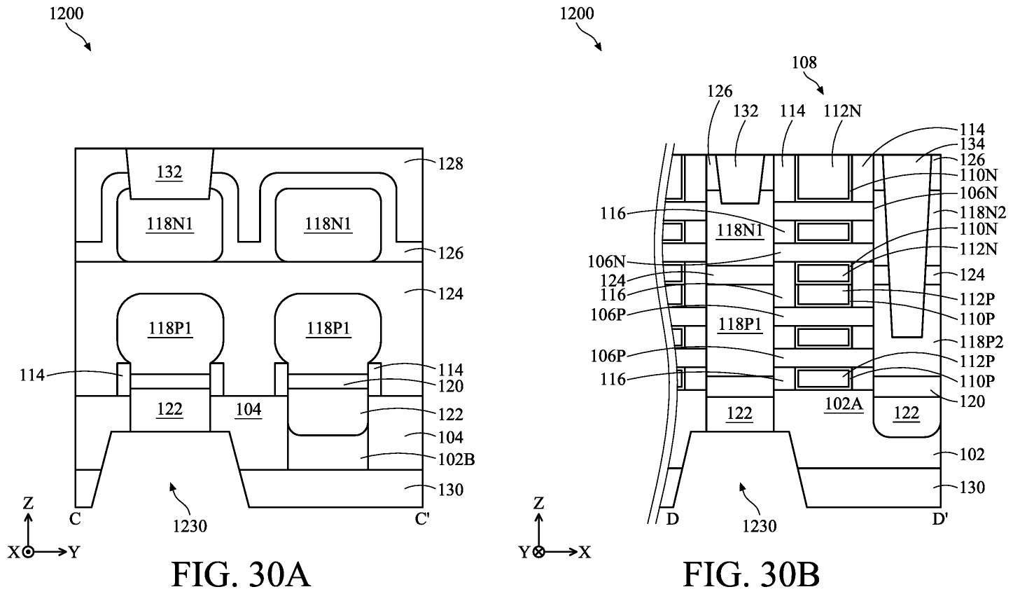

Referring to FIGS. 30A and 30B, an opening 1230 is formed on backside of the workpiece 1200 to expose the SiGe layer 122, in accordance with some embodiments. In some embodiments, one or more photolithography and etching processes are performed to etch the ILD layer 130, the isolation structures 104, and the substrate 102, so as to form the opening 1230 that exposes the SiGe layer. In some embodiments, the exposed SiGe layer 122 is also partially etched. In some embodiments, the etching processes may be dry etching processes, wet etching processes, other suitable etching processes, or combinations thereof. In some embodiments, the ILD layer 130, the isolation structures 104, and the substrate 102 (including base portion 102A) under the source/drain feature 118P1 of the CFET 100A are etched, such that the opening 1230 is formed under the source/drain feature 118P1 of the CFET 100A. Therefore, in some embodiments, the SiGe layer under source/drain feature 118P1 of the CFET 100A is exposed by the opening 1230, as shown in FIGS. 30A and 30B.

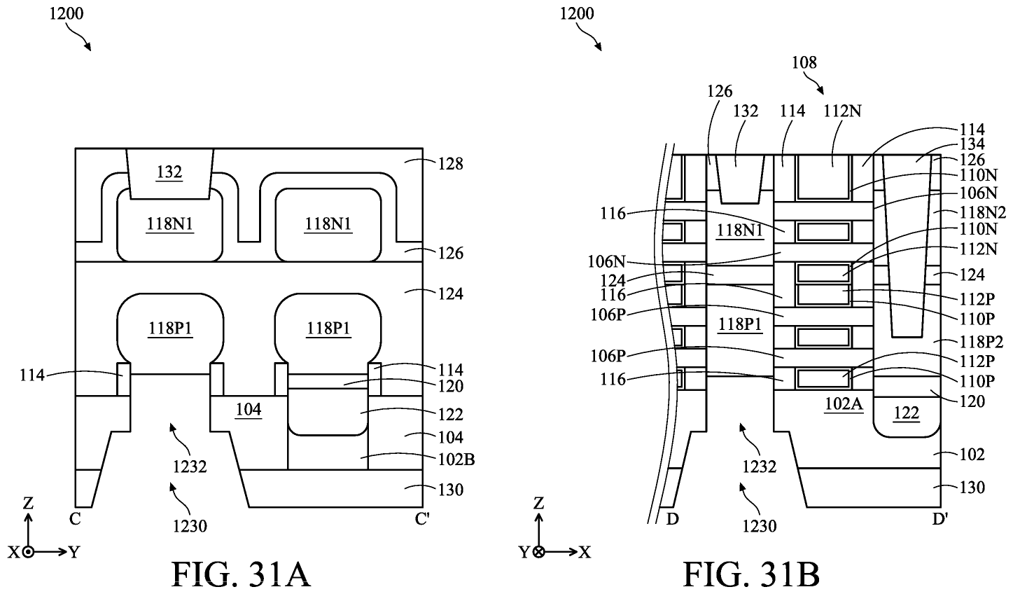

Referring to FIGS. 31A and 31B, the SiGe layer 122 and the bottom isolation layer 120 are removed through the opening 1230 to form an opening 1232, such that the opening 1230 and the opening 1232 collectively expose the source/drain feature 118P, in accordance with some embodiments. In some embodiments, the bottommost one of inner spacers 116 is also exposed by the opening 1232. In some embodiments, a selective etching process is performed to remove the SiGe layer 122 through the opening 1230. In some embodiments, the selective etching process is performed that selectively etches the SiGe layer 122, with minimal etching (or substantially no etching) of the inner spacers 116, the ILD layer 130, the isolation structures 104, and the substrate 102. After removing the SiGe layer 122, a selective etching process is performed to remove the bottom isolation layer 120, in accordance with some embodiments. In some embodiments, the selective etching process is performed that selectively etches the bottom isolation layer 120, with minimal etching (or substantially no etching) of the inner spacers 116, the gate spacers 114, the ILD layer 130, the isolation structures 104, and the substrate 102. The selective etching processes of the SiGe layer 122 and the bottom isolation layer 120 may be dry etching processes, wet etching processes, other suitable etching processes, or combinations thereof.

After removing the SiGe layer 122 and the bottom isolation layer 120, the opening 1232 is formed in the place previously held by the SiGe layer 122 and the bottom isolation layer 120, and then the source/drain feature 118P is exposed by the openings 1232 and 1230. In some embodiments, the SiGe layer 122 and the bottom isolation layer 120 under the source/drain feature 118P1 of the CFET 100A are removed, such that the opening 1232 is formed under the source/drain feature 118P1 of the CFET 100A. Therefore, in some embodiments, the source/drain feature 118P1 of the CFET 100A is exposed by the openings 1230 and 1232, as shown in FIGS. 31A and 31B. In some embodiments, a Y-direction width of the opening 1230 is greater than a Y-direction width of the opening 1232, and an X-direction width of the opening 1230 is greater than an X-direction width of the opening 1232.

By forming the SiGe layer 122 below the source/drain feature 118P and removing the SiGe layer 122 by a selective etching process, the opening 1232 and the source/drain contact (e.g., source/drain contacts 140-1040) that will be formed in the opening 1232 may be formed by a self-aligned process. Which can keep the opening 1232 and the source/drain contact formed in the opening 1232 from contacting other conductive components. In this way, the entire space held by the SiGe layer 122 may be utilized effectively to form the source/drain contact. Therefore, the dimensions of the source/drain contact can be enlarged as much as possible to reduce the resistance, and the problem of short-circuits occurring with other conductive components can be avoided at the same time.

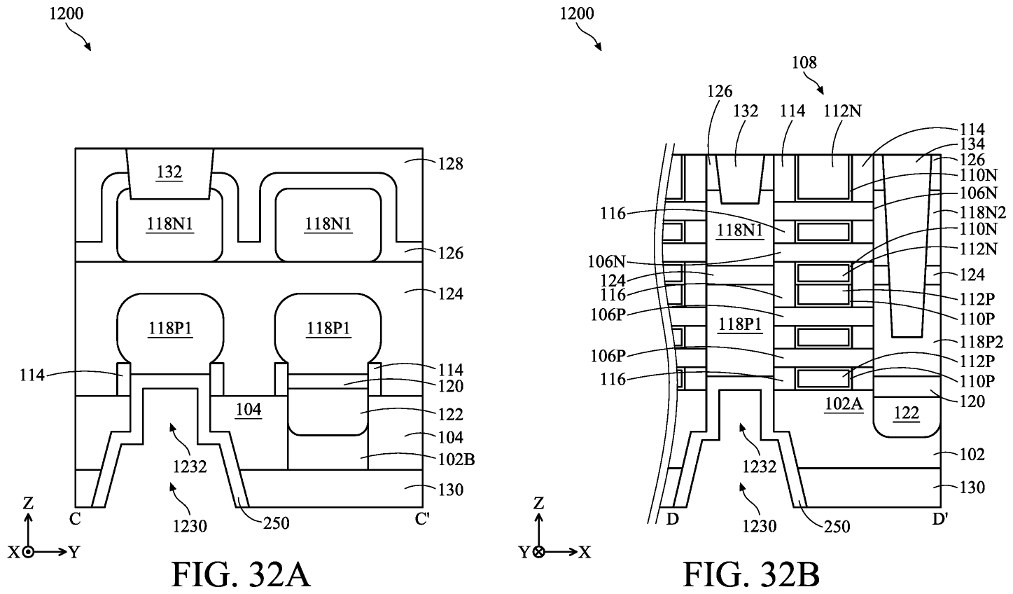

Referring to FIGS. 32A and 32B, the sidewall dielectric layer 250 is formed on sidewalls of the openings 1230 and 1232 and the bottom surface of the source/drain feature 118P (e.g., the source/drain feature 118P1 of the CFET 100A in some embodiments), in accordance with some embodiments. In other words, the sidewall dielectric layer 250 is formed on sidewalls of the ILD layer 130, the isolation structures 104, and the substrate 102 that are exposed by the openings 1230 and 1232. In some embodiments, the material of the sidewall dielectric layer 250 may include silicon nitride (Si₃N₄), silicon oxide (SiO₂), SiC, SiOC, SiON, SiCN, SiOCN, high-k dielectrics, other suitable materials, or combinations thereof. In some embodiments, the sidewall dielectric layer 250 may be deposited by CVD, PVD, ALD, HDPCVD, MOCVD, RPCVD, PECVD, LPCVD, ALCVD, APCVD, other suitable methods, or combinations thereof. The materials and methods used in forming the sidewall dielectric layer 250 may be adopted to the sidewall dielectric layers 550-650.

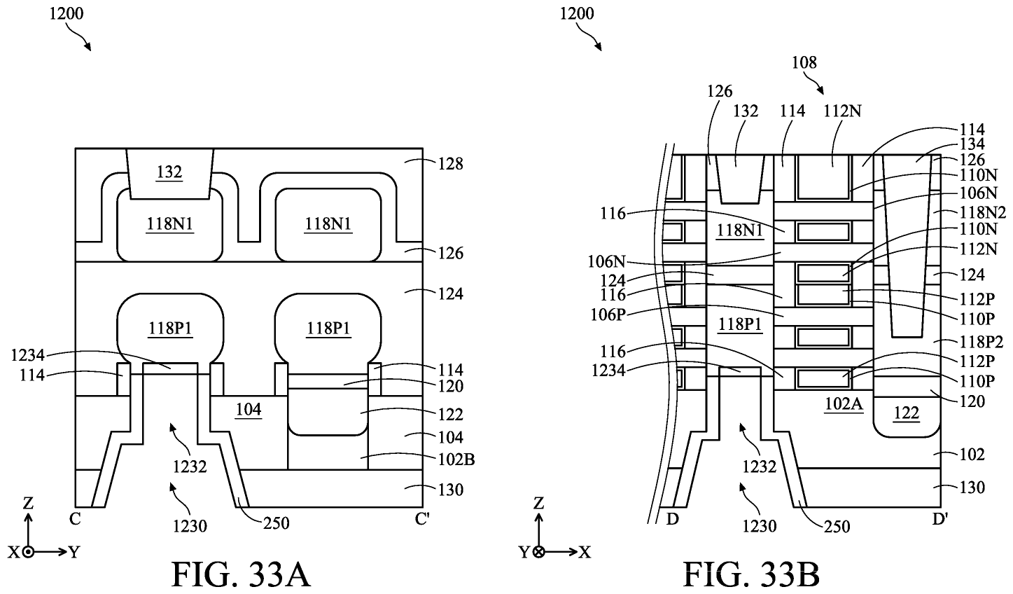

Referring to FIGS. 33A and 33B, a horizontal portion of the sidewall dielectric layer 250 is removed, in accordance with some embodiments. In some embodiments, an anisotropic etching process is performed to remove the horizontal portion of sidewall dielectric layer 250 to expose the bottom surface of the source/drain feature 118P (e.g., the source/drain feature 118P1 of the CFET 100A in some embodiments). In some embodiments, the anisotropic etching process is a dry (e.g., plasma) etching process.

Still referring to FIGS. 33A and 33B, a silicide layer 1234 is formed on bottom surface of the source/drain feature 118P that is exposed by the opening 1230 and 1232, in accordance with some embodiments. In some embodiments, the silicide layer 1234 is formed on bottom surface of the source/drain feature 118P1 of the CFET 100A. In some embodiments, the silicide layers 1234 may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

In some aspects, the formation of the silicide layer 1234 may be adopted to the semiconductor devices 100-1100 shown in FIGS. 1A-11B. For example, a silicide layer may be formed at the interface between the source/drain feature and the source/drain contact of the semiconductor devices 100-1100. In other aspects, the formation of the silicide layer 1234 may be omitted, and the resultant device of the workpiece 1200 may be fabricated to as the semiconductor devices 100-1100 shown in FIGS. 1A-11B. In some aspects, the formation of the sidewall dielectric layer 250 may be omitted, and the resultant device of the workpiece 1200 may be fabricated to as the semiconductor devices 100, 300-400, and 700-800 shown in FIGS. 1A and 1B, 3-4, and 7-8.

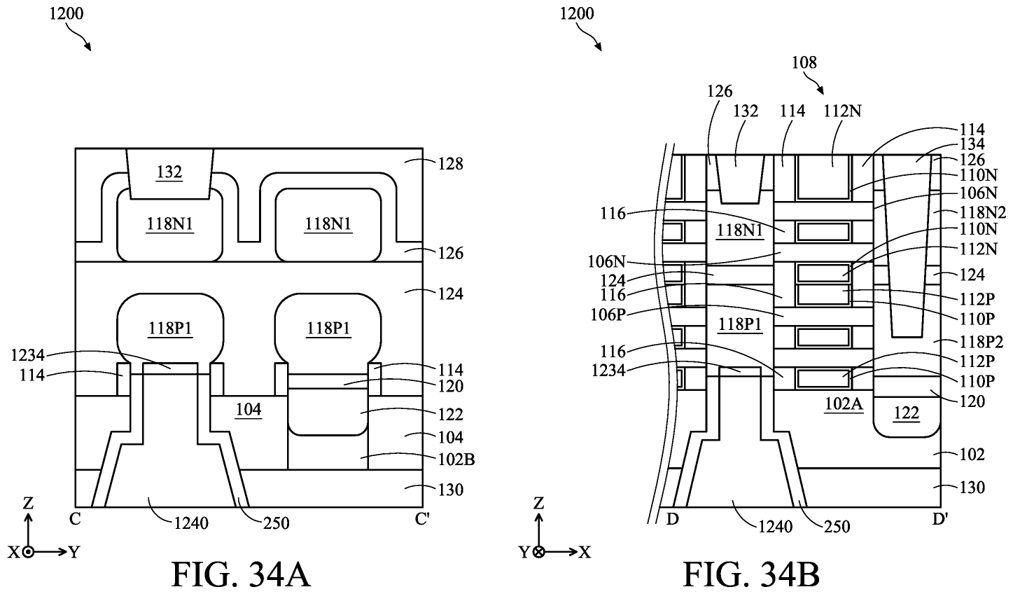

Referring to FIGS. 34A and 34B, a conductive material is deposited in the openings 1230 and 1232 to form a source/drain contact 1240, in accordance with some embodiments. In some embodiments, the source/drain contact 1240 may include a conductive material such as Al, Cu, W, Co, Ti, Ta, Ru, Rh, Ir, Pt, Mo, TiN, TiAl, TiAlN, TaN, TaC, combinations of these, or the like, although any suitable material may be deposited using a deposition process such as sputtering, CVD, PVD, ALD, HDPCVD, MOCVD, RPCVD, PECVD, LPCVD, ALCVD, APCVD, FCVD, electroplating, electroless plating, or the like. However, any suitable materials and processes may be utilized to form source/drain contact 1240. In some embodiments, the source/drain contact 1240 may include a single conductive material layer or multiple conductive layers. The materials and the methods used in forming the source/drain contact 1240 may be adopted to the source/drain contacts 140-1040 described above.

In some embodiments, the source/drain contact 1240 is under, in contact with, and electrically connected to the source/drain feature 118P1 (and the silicide layer 1234) of the CFET 100A, as shown in FIGS. 34A and 34B. In some embodiments, similar to the source/drain contact 140, the source/drain contact 1240 includes an upper portion that is in contact with the source/drain feature 118P and a lower portion that is below the upper portion in the Z-direction, wherein the dimensions of the lower portion are greater than dimensions of the upper portion in the X-direction and the Y-direction.

In the embodiments where the silicide layer 1234 is omitted, the resultant device of the workpiece 1200 may be fabricated to as the semiconductor device 200 shown in FIGS. 2A and 2B. In the embodiments where the silicide layer 1234 and the sidewall dielectric layer 250 are omitted, the resultant device of the workpiece 1200 may be fabricated to as the semiconductor device 100 shown in FIGS. 1A and 1B. In the embodiments where the silicide layer 1234, the sidewall dielectric layer 250, and the bottom isolation layer 120 are omitted, the resultant device of the workpiece 1200 may be fabricated to as the semiconductor device 1100 shown in FIGS. 11A and 11B.

In some embodiments, after forming the sidewall dielectric layer 250 and before forming the source/drain contact 1240, an additional etching process is performed to partially etching the source/drain feature 118P and form a recess in the source/drain feature 118P. Then, the source/drain contact 1240 is formed in the recess and the openings 1230 and 1232. In these embodiments, the resultant device of the workpiece 1200 may be fabricated to as the semiconductor device 900 shown in FIGS. 9A and 9B. In some embodiments, the sidewall dielectric layer 250 is formed before removing the bottom isolation layer 120, and the etching process for etching the bottom isolation layer 120 further partially etches the source/drain feature 118P and form a recess in the source/drain feature 118P. Then, the source/drain contact 1240 is formed in the recess and the openings 1230 and 1232. In these embodiments, the resultant device of the workpiece 1200 may be fabricated to as the semiconductor device 1000 shown in FIGS. 10A and 10B.

In the embodiments where the additional etching process is performed form the recess in the source/drain feature 118P, a silicide layer can be formed on surfaces of the source/drain feature 118P exposed by the recess. In these embodiments, the top portion of the source/drain contact that formed in the recess and extending in to the source/drain feature 118P can be covered by the silicide layer. For example, the top surface and sidewalls of the top portion of the source/drain contact can be covered by the silicide layer.

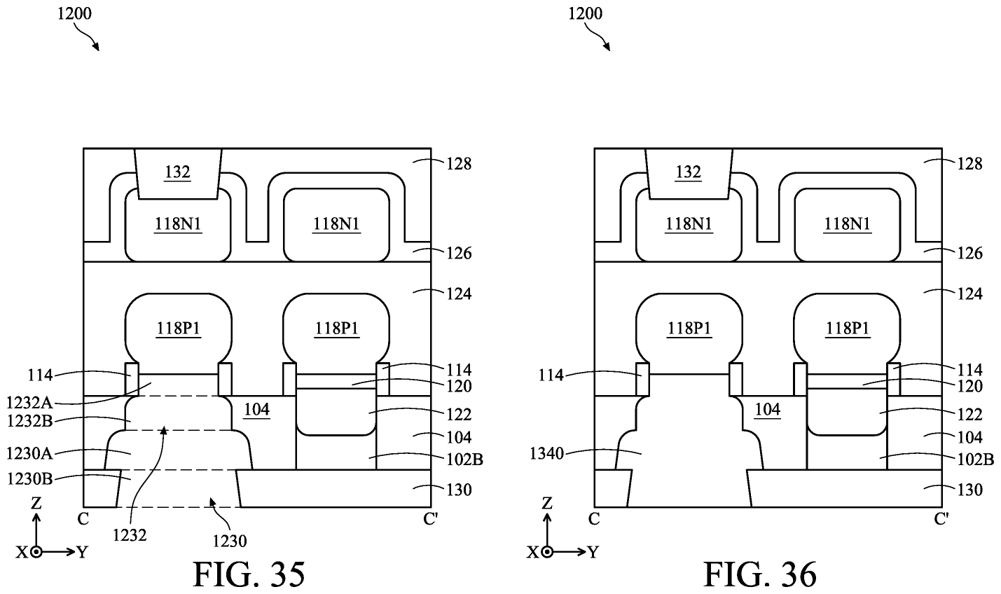

Referring to FIG. 35, the fabrication stage shown in FIG. 35 follows the fabrication stage shown in FIGS. 31A and 31B. In some embodiments, the opening 1230 and the opening 1232 are selectively etched to be enlarged in the Y-direction through a selective etching process. In these embodiments, the selective etching process is performed that selectively and laterally etches the isolation structures 104 in the Y-direction, so as to enlarge the openings 1230 and 1232 in the Y-direction, with minimal etching (or substantially no etching) of the ILD layer 130, substrate 102, the gate spacers 114, the inner spacers 116, and the source/drain feature 118P.

In some embodiments, a portion 1232B of the opening 1232 that is inside the isolation structures 104 is enlarged in the Y-direction since the isolation structures 104 are selectively etched. In these embodiments, a portion 1232A of the opening 1232 that is outside the isolation structures 104 is not or substantially not affected since the surrounding components (e.g., the gate spacers 114 and the source/drain feature 118P) are not etched by the selective etching process. Therefore, a Y-direction width of the portion 1232B of the opening 1232 is greater than a Y-direction width of the portion 1232A of the opening 1232, as shown in FIG. 35.

In some embodiments, a portion 1230A of the opening 1230 that is inside the isolation structures 104 is enlarged in the Y-direction since the isolation structures 104 are selectively etched. In these embodiments, a portion 1230B of the opening 1230 that is outside the isolation structures 104 (i.e., inside the ILD layer 130) is not or substantially not affected since the surrounding components (e.g., the ILD layer 130) are not etched by the selective etching process. Therefore, a Y-direction width of the portion 1230A of the opening 1230 is greater than a Y-direction width of the portion 1230B of the opening 1230, as shown in FIG. 35. In some embodiments, the Y-direction width of the portion 1230A of the opening 1230 is greater than the Y-direction width of the portion 1232B of the opening 1232.

In some embodiments, in the Y-Z plane, top corners of the portion 1230A of the opening 1230 are rounded, and/or top corners of the portion 1232B of the opening 1232 are rounded, as shown in FIG. 35. In some embodiments, the Y-direction width of the portion 1232B of the opening 1232 is greater than the Y-direction width of the portion 1230B of the opening 1230 in the Y-direction. In other embodiments, the Y-direction width of the portion 1232B of the opening 1232 is smaller than or the same as the Y-direction width of the portion 1230B of the opening 1230 in the Y-direction.

Referring to FIG. 36, after enlarging the opening 1230 and the opening 1232 in the Y-direction, a conductive material is deposited in the openings 1230 and 1232 to form a source/drain contact 1340, in accordance with some embodiments. In some embodiments, the materials and methods used in forming the source/drain contact 1340 are the same as or similar to those of the source/drain contact 1240. In these embodiments, the resultant device of the workpiece 1200 may be fabricated to as the semiconductor device 700 shown in FIG. 7. In some embodiments, before forming the source/drain contact 1340, a sidewall dielectric layer may be formed on sidewalls of the openings 1230 and 1232 to improve the isolation between the source/drain contact 1340 and surrounding components.

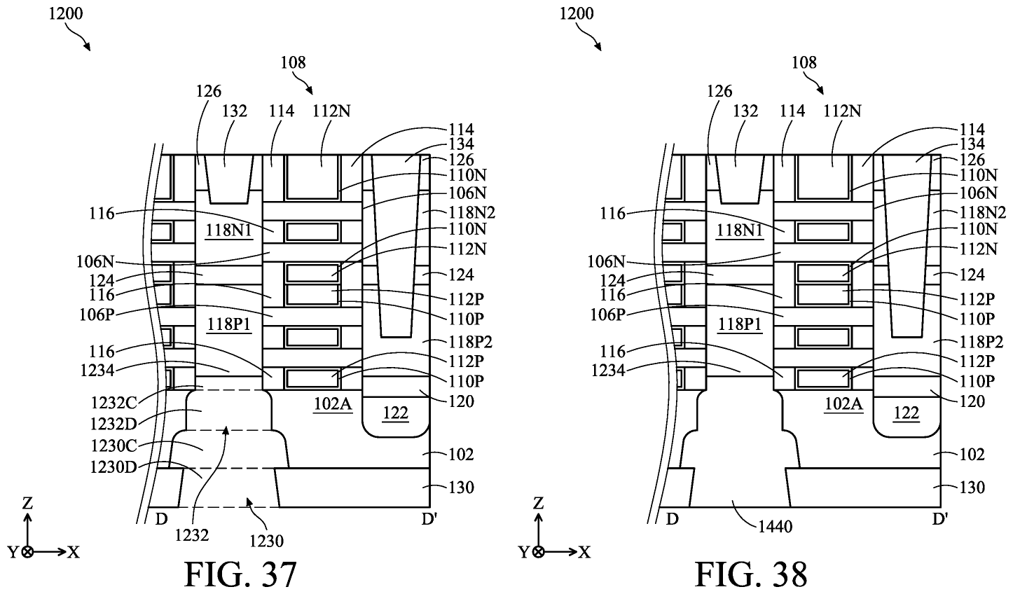

Referring to FIG. 37, the fabrication stage shown in FIG. 37 follows the fabrication stage shown in FIGS. 31A and 31B. In some embodiments, the opening 1230 and the opening 1232 are selectively etched to be enlarged in the X-direction through a selective etching process. In these embodiments, the selective etching process is performed that selectively and laterally etches the substrate 102 in the X-direction, so as to enlarge the openings 1230 and 1232 in the X-direction, with minimal etching (or substantially no etching) of the ILD layer 130, the isolation structures 104, the gate spacers 114, the inner spacers 116, and the source/drain feature 118P.

In some embodiments, a portion 1232D of the opening 1232 that is inside the substrate 102 is enlarged in the X-direction since the substrate 102 is selectively etched. In these embodiments, a portion 1232C of the opening 1232 that is outside the substrate 102 is not or substantially not affected since the surrounding components (e.g., the inner spacers 116 and the source/drain feature 118P) are not etched by the selective etching process. Therefore, an X-direction width of the portion 1232D of the opening 1232 is greater than an X-direction width of the portion 1232C of the opening 1232, as shown in FIG. 37.

In some embodiments, a portion 1230C of the opening 1230 that is inside the substrate 102 is enlarged in the X-direction since the substrate 102 is selectively etched. In these embodiments, a portion 1230D of the opening 1230 that is outside the substrate 102 (i.e., inside the ILD layer 130) is not or substantially not affected since the surrounding components (e.g., the ILD layer 130) are not etched by the selective etching process. Therefore, an X-direction width of the portion 1230C of the opening 1230 is greater than an X-direction width of the portion 1230D of the opening 1230 in the X-direction, as shown in FIG. 37. In some embodiments, the X-direction width of the portion 1230C of the opening 1230 is greater than the X-direction width of the portion 1232D of the opening 1232.

In some embodiments, in the X-Z plane, top corners of the portion 1230C of the opening 1230 are rounded, and/or top corners of the portion 1232D of the opening 1232 are rounded, as shown in FIG. 37. In some embodiments, the X-direction width of the portion 1232D of the opening 1232 is greater than the X-direction width of the portion 1230D of the opening 1230 in the X-direction. In other embodiments, the X-direction width of the portion 1232D of the opening 1232 is smaller than or the same as the X-direction width of the portion 1230D of the opening 1230 in the X-direction.

Referring to FIG. 38, after enlarging the opening 1230 and the opening 1232 in the X-direction, a conductive material is deposited in the openings 1230 and 1232 to form a source/drain contact 1440, in accordance with some embodiments. In some embodiments, the materials and methods used in forming the source/drain contact 1440 are the same as or similar to those of the source/drain contact 1240. In these embodiments, the resultant device of the workpiece 1200 may be fabricated to as the semiconductor device 800 shown in FIG. 8. In some embodiments, before forming the source/drain contact 1440, a sidewall dielectric layer may be formed on sidewalls of the openings 1230 and 1232 to improve the isolation between the source/drain contact 1440 and surrounding components.

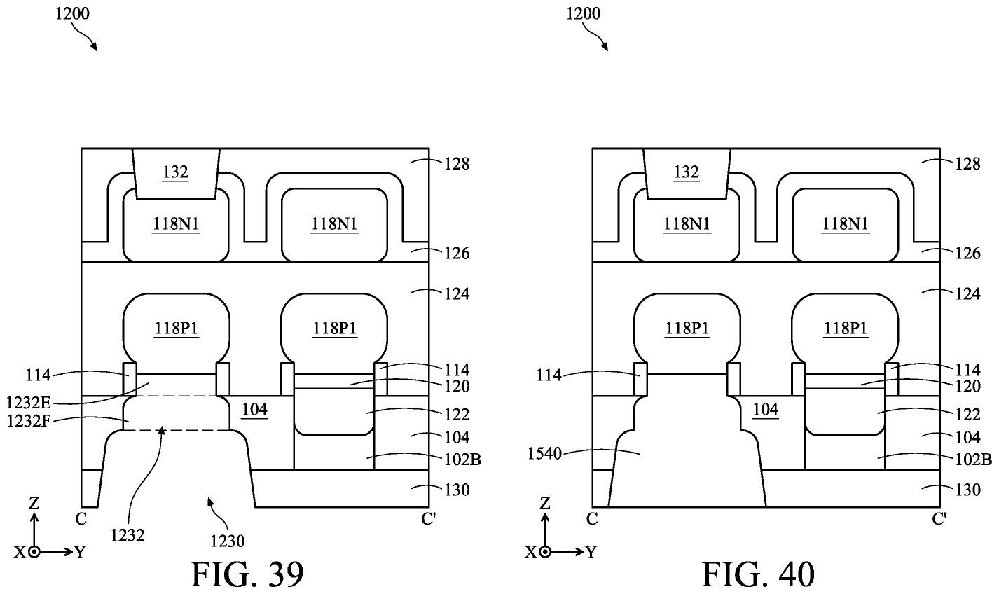

Referring to FIG. 39, the fabrication stage shown in FIG. 39 follows the fabrication stage shown in FIGS. 31A and 31B. In some embodiments, the opening 1230 and the opening 1232 are selectively etched to be enlarged in the Y-direction through a selective etching process. In these embodiments, the selective etching process is performed that selectively and laterally etches the isolation structures 104 and the ILD layer 130 in the Y-direction, so as to enlarge the openings 1230 and 1232 in the Y-direction, with minimal etching (or substantially no etching) of the substrate 102, the gate spacers 114, the inner spacers 116, and the source/drain feature 118P.

In some embodiments, a portion 1232F of the opening 1232 that is inside the isolation structures 104 is enlarged in the Y-direction since the isolation structures 104 are selectively etched. In these embodiments, a portion 1232E of the opening 1232 that is outside the isolation structures 104 is not or substantially not affected since the surrounding components (e.g., the gate spacers 114 and the source/drain feature 118P) are not etched by the selective etching process. Therefore, a Y-direction width of the portion 1232F of the opening 1232 is greater than a Y-direction width of the portion 1232E of the opening 1232, as shown in FIG. 39.

In some embodiments, the opening 1230 that is enlarged in the Y-direction since the isolation structures 104 and the ILD layer 130 are selectively etched. In these embodiments, a Y-direction width of the opening 1230 is greater than the Y-direction widths of the portions 1232E and 1232F of the opening 1232 since the opening 1230 is also enlarged in the Y-direction. In some embodiments, in the Y-Z plane, top corners of the opening 1230 are rounded, and/or top corners of the portion 1232F of the opening 1232 are rounded, as shown in FIG. 39.

Referring to FIG. 40, after enlarging the opening 1230 and the opening 1232 in the Y-direction, a conductive material is deposited in the openings 1230 and 1232 to form a source/drain contact 1540, in accordance with some embodiments. In some embodiments, the materials and methods used in forming the source/drain contact 1540 are the same as or similar to those of the source/drain contact 1240. In these embodiments, the resultant device of the workpiece 1200 may be fabricated to as the semiconductor device 300 shown in FIG. 3. In some embodiments, before forming the source/drain contact 1540, a sidewall dielectric layer may be formed on sidewalls of the openings 1230 and 1232 to improve the isolation between the source/drain contact 1540 and surrounding components. In these embodiments, the resultant device of the workpiece 1200 may be fabricated to as the semiconductor device 500 shown in FIG. 5.

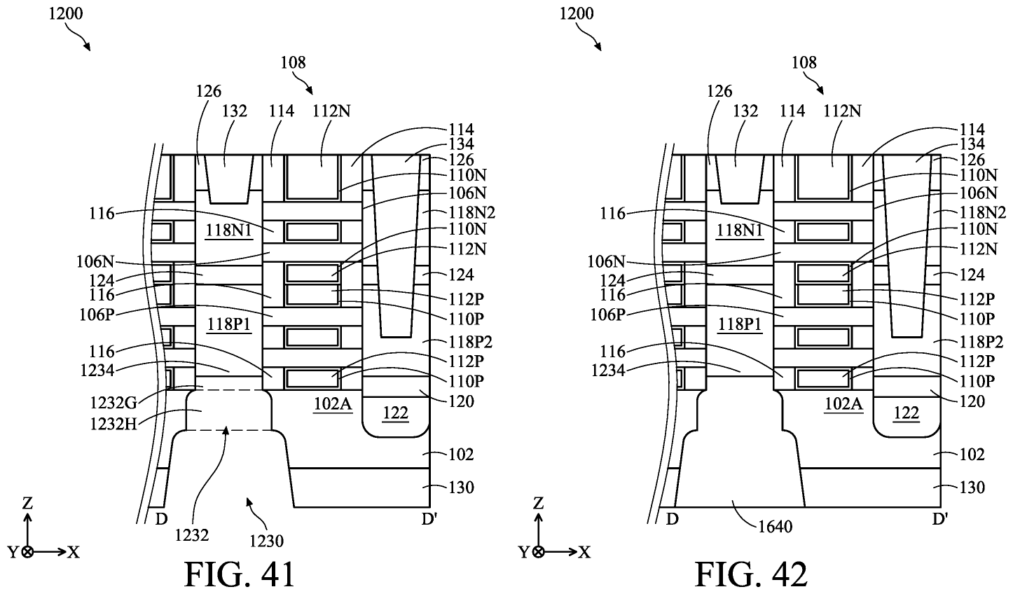

Referring to FIG. 41, the fabrication stage shown in FIG. 41 follows the fabrication stage shown in FIGS. 31A and 31B. In some embodiments, the opening 1230 and the opening 1232 are selectively etched to be enlarged in the X-direction through a selective etching process. In these embodiments, the selective etching process is performed that selectively and laterally etches the substrate 102 and the ILD layer 130 in the X-direction, so as to enlarge the openings 1230 and 1232 in the X-direction, with minimal etching (or substantially no etching) of the isolation structures 104, the gate spacers 114, the inner spacers 116, and the source/drain feature 118P.

In some embodiments, a portion 1232H of the opening 1232 that is inside the substrate 102 is enlarged in the X-direction since the substrate 102 is selectively etched. In these embodiments, a portion 1232G of the opening 1232 that is outside the substrate 102 is not or substantially not affected since the surrounding components (e.g., the inner spacers 116 and the source/drain feature 118P) are not etched by the selective etching process. Therefore, an X-direction width of the portion 1232H of the opening 1232 is greater than an X-direction width of the portion 1232G of the opening 1232, as shown in FIG. 41.

In some embodiments, the opening 1230 is enlarged in the X-direction since the substrate 102 and the ILD layer 130 are selectively etched. In these embodiments, an X-direction width of the opening 1230 is greater than the X-direction widths of the portions 1232G and 1232H of the opening 1232 since the opening 1230 is also enlarged in the X-direction. In some embodiments, in the X-Z plane, top corners of the opening 1230 are rounded, and/or top corners of the portion 1232H of the opening 1232 are rounded, as shown in FIG. 41.

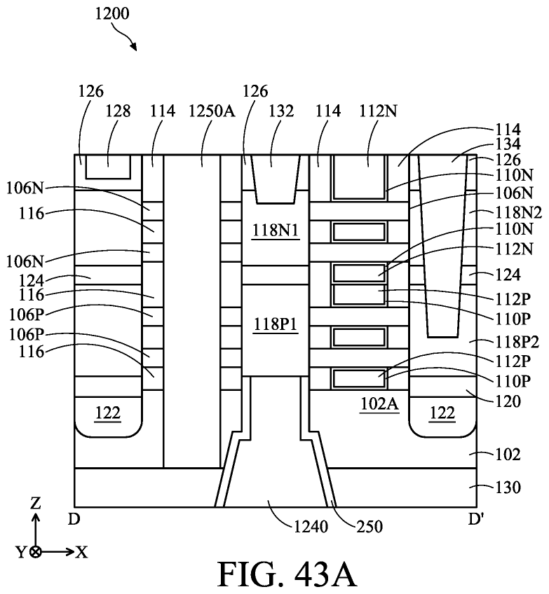

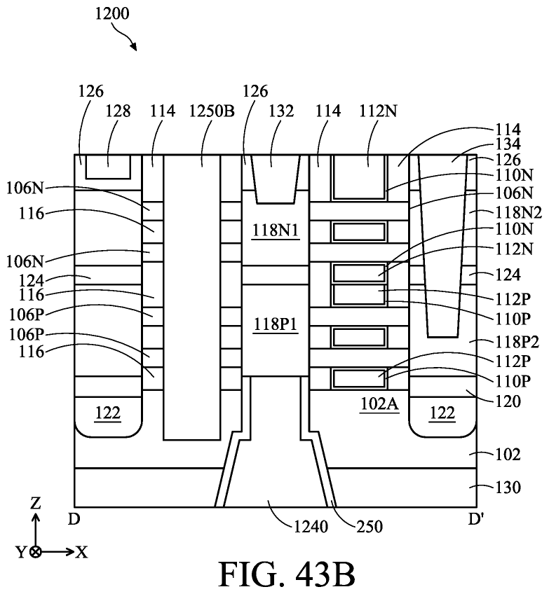

Referring to FIG. 42, after enlarging the opening 1230 and the opening 1232 in the X-direction, a conductive material is deposited in the openings 1230 and 1232 to form a source/drain contact 1640, in accordance with some embodiments. In some embodiments, the materials and methods used in forming the source/drain contact 1640 are the same as or similar to those of the source/drain contact 1240. In these embodiments, the resultant device of the workpiece 1200 may be fabricated to as the semiconductor device 400 shown in FIG. 4. In some embodiments, before forming the source/drain contact 1640, a sidewall dielectric layer may be formed on sidewalls of the openings 1230 and 1232 to improve the isolation between the source/drain contact 1640 and surrounding components. In these embodiments, the resultant device of the workpiece 1200 may be fabricated to as the semiconductor device 600 shown in FIG. 6.

In some embodiments, the selective etching process for enlarging the openings 1230 and 1232 can be configured to selectively etch the ILD layer 130, the isolation structures 104, and the substrate 102, with minimal etching (or substantially no etching) of the gate spacers 114, the inner spacers 116, and the source/drain feature 118P. In these embodiments, the openings 1230 and 1232 can be enlarged in the X-direction and the Y-direction at the same time.

FIG. 43A is an X-Z cross-sectional view of the workpiece 1200, in accordance with some embodiments of the present disclosure. In some embodiments, the workpiece 1200 further includes a dielectric gate structure 1250A, as shown in FIG. 43A. The dielectric gate structure 1250A may be used to isolate the CFET device (e.g., CFETs 100A and 100B discussed above) from other devices. In some embodiments, the dielectric gate structure 1250A is formed in a non-functional channel region adjacent to the CFET device, and extends in the non-functional channel region along the Z-direction. In some embodiments, the dielectric gate structure 1250A extends through the nanostructures 106 and into the substrate 102.

In some embodiments, the formation of the dielectric gate structure 1250A follows the fabrication stage shown in FIGS. 24A and 24B. In these embodiments, the formation of the dielectric gate structure 1250A may include performing one or more etching processes to etch the dummy gate structure 1214, the semiconductor layers 1206 and 1208, and the substrate 102, so as to form a trench. Then, a dielectric material may be deposited in the trench by a deposition process to form the dielectric gate structure 1250A. In further embodiments, the etching processes also partially etch the gate spacers 114 and/or the inner spacers 116, so that the dielectric gate structure 1250A formed in the trench is also in contact with the gate spacers 114 and/or the inner spacers 116.

In some embodiments, the formation of the dielectric gate structure 1250A follows the fabrication stage shown in FIGS. 28A and 28B. In these embodiments, the formation of the dielectric gate structure 1250A may include performing one or more etching processes to etch the gate structure 108, the nanostructures 106, and the substrate 102, so as to form a trench. Then, a dielectric material may be deposited in the trench by a deposition process to form the dielectric gate structure 1250A. In further embodiments, the etching processes also partially etch the gate spacers 114 and/or the inner spacers 116, so that the dielectric gate structure 1250A formed in the trench is also in contact with the gate spacers 114 and/or the inner spacers 116.

In some embodiments, the material of the dielectric gate structure 1250A may include silicon nitride (Si₃N₄), silicon oxide (SiO₂), SiC, SiOC, SiON, SiCN, SiOCN, high-k dielectrics, other suitable materials, or combinations thereof. In some embodiments, the dielectric gate structure 1250A may be deposited by CVD, PVD, ALD, HDPCVD, MOCVD, RPCVD, PECVD, LPCVD, ALCVD, APCVD, other suitable methods, or combinations thereof.

In some embodiments, the dielectric gate structure 1250A extends to contact the ILD layer 130 formed under the substrate 102. That is, the dielectric gate structure 1250A penetrates the substrate 102 that has been thinned and is in contact with the bottom surface of the substrate 102, as shown in FIG. 43A.

FIG. 43B is an X-Z cross-sectional view of the workpiece 1200, in accordance with alternative embodiments of the present disclosure. The structure shown in FIG. 43B may be similar to the structure shown in FIG. 43A, except the dielectric gate structure 1250A shown in FIG. 43A is replaced by a dielectric gate structure 1250B shown in FIG. 43B. In some embodiments, similar to the dielectric gate structure 1250A, the dielectric gate structure 1250B extends through the nanostructures 106 and into the substrate 102. However, the dielectric gate structure 1250B is shallower than the dielectric gate structure 1250A. That is, although the dielectric gate structure 1250B extends into the substrate 102, there is still a portion of the substrate 102 between the dielectric gate structure 1250B and the ILD layer 130, as shown in FIG. 43B. In some embodiments, the materials and method used in forming the dielectric gate structure 1250B are the same as or similar to those of the dielectric gate structure 1250A.

The embodiments disclosed herein relate to semiconductor structures and their forming methods, and more particularly to methods and semiconductor structures that include forming SiGe layers below the source/drain features of the bottom FET in the CFET. When a backside source/drain contact is formed on the backside of the CFET, the SiGe layer can be selectively removed to form an opening for forming the backside source/drain contact. In this way, the backside source/drain contact can be formed by the self-aligned process that can keep the backside source/drain contact from contacting other conductive components. As a result, the dimensions of the backside source/drain contact can be enlarged as much as possible, so as to reduce the resistance while avoiding the occurrence of a short-circuit with other conductive components. Moreover, the opening formed by selectively removing the SiGe layer can be laterally enlarged even further, so as to increase the dimensions of the opening and the source/drain contact to be formed inside the opening. As a result, the resistance of the backside source/drain contact can be reduced further.

In one exemplary aspect, the present disclosure is directed to a method of forming a semiconductor structure. The method includes forming a fin structure over a substrate, wherein the fin structure includes first semiconductor layers and second semiconductor layers alternately stacked; forming a first source/drain trench and a second source/drain trench in the fin structure; forming a first SiGe layer and a second SiGe layer in the first source/drain trench and the second source/drain trench, respectively; forming a first source/drain feature and a second source/drain feature over the first SiGe layer and the second SiGe layer in the first source/drain trench and the second source/drain trench, respectively; and forming a third source/drain feature and a fourth source/drain feature over and separated from the first source/drain feature and the second source/drain feature, respectively. The method further includes removing the first semiconductor layers; forming a gate structure to wrap around the second semiconductor layers; forming a first interlayer dielectric (ILD) layer on a backside of the substrate; etching the first ILD layer and the substrate to form a first opening that exposes the first SiGe layer; removing the first SiGe layer through the first opening to form a second opening that exposes the first source/drain feature; and depositing a conductive material in the first opening and the second opening to form a first source/drain contact. The lateral dimensions of the first opening are greater than those of the second opening in an X-direction and a Y-direction, which is perpendicular to the X-direction.

In another exemplary aspect, the present disclosure is directed to a method of forming a semiconductor structure. The method includes forming a fin structure extending in an X-direction over a substrate, wherein the fin structure includes first semiconductor layers and second semiconductor layers alternately stacked; forming a dummy gate structure over the fin structure and extending in a Y-direction; forming a first SiGe layer and a second SiGe layer on opposite sides of the dummy gate structure in the X-direction; forming a first source/drain feature and a second source/drain feature over the first SiGe layer and the second SiGe layer, respectively; and forming a third source/drain feature and a fourth source/drain feature. The first source/drain feature and the second source/drain feature are attached to a first group of the second semiconductor layers, and the third source/drain feature and the fourth source/drain feature are attached to a second group of the second semiconductor layers. The method further includes thinning the substrate; forming a first interlayer dielectric (ILD) layer on a backside of the substrate; forming a first opening in the first ILD layer and the substrate to expose the first SiGe layer; and removing the first SiGe layer through the first opening to form a second opening that exposes the first source/drain feature. The lateral dimensions of the first opening are greater than those of the second opening in the X-direction and the Y-direction. The method further includes forming a sidewall dielectric layer on sidewalls of the first opening and the second opening, and depositing a conductive material to fill remaining spaces of the first opening and the second opening to form a first source/drain contact.

In yet another exemplary aspect, the present disclosure is directed to a semiconductor structure. The semiconductor structure includes a first transistor and a second transistor over the first transistor. The first transistor includes first nanostructures over a substrate, wherein the first nanostructures are spaced apart from each other in a Z-direction; and a first source/drain feature and a second source/drain feature, attached to opposite sides of the first nanostructures in an X-direction. The second transistor includes second nanostructures over the first nanostructures, wherein the second nanostructures are spaced apart from each other in the Z-direction; and a third source/drain feature and a fourth source/drain feature, attached to opposite sides of the second nanostructures in the X-direction and being over the first source/drain feature and the second source/drain feature, respectively. The semiconductor structure further includes a gate structure wrapped around the first nanostructures and the second nanostructures; and a first source/drain contact, passing through the substrate and being in contact with the first source/drain feature. The first source/drain contact includes a first portion in contact with the first source/drain feature and a second portion below the first portion. The Y-direction width of the second portion is greater than the Y-direction width of the first portion in the Y-direction, which is perpendicular to the X-direction.

In some embodiments, the second portion of the first source/drain contact has a first sub-portion surrounded by the isolation structures in the Y-direction and a second sub-portion surrounded by the first ILD layer, and a Y-direction width of the first sub-portion of the second portion is greater than a Y-direction width of the second sub-portion of the second portion in the Y-direction.

In some embodiments, the first portion of the first source/drain contact has a first sub-portion outside the isolation structures and a second sub-portion surrounded by the isolation structures in the Y-direction, and a Y-direction width of the first sub-portion of the first portion is smaller than a Y-direction width of the second sub-portion of the first portion in the Y-direction.

In yet another exemplary aspect, the present disclosure is directed to a method of forming a semiconductor structure. The method includes forming a fin structure over a substrate, wherein the fin structure includes first semiconductor layers and second semiconductor layers alternately stacked; forming a first source/drain trench and a second source/drain trench in the fin structure; forming a first SiGe layer and a second SiGe layer in the first source/drain trench and the second source/drain trench, respectively; forming a first source/drain feature and a second source/drain feature over the first SiGe layer and the second SiGe layer, respectively; and forming a third source/drain feature and a fourth source/drain feature over the first source/drain feature and the second source/drain feature, respectively. The method further includes forming a first interlayer dielectric (ILD) layer on a backside of the substrate; etching the first ILD layer and the substrate to form a first opening that exposes the first SiGe layer; and removing the first SiGe layer through the first opening to form a second opening that exposes the first source/drain feature. The lateral dimensions of the first opening are greater than those of the second opening in the X-direction and the Y-direction that is perpendicular to the X-direction. The method further includes forming a silicide layer on a surface of the first source/drain feature exposed by the first opening and the second opening; and depositing a conductive material to fill remaining spaces of the first opening and the second opening to form a first source/drain contact.

In some embodiments, the method further includes forming isolation structures on opposite sides of the fin structure in the Y-direction. The formation of the first opening further includes partially etching the isolation structures. In some embodiments, the method further includes laterally etching the isolation structures to enlarge the first opening and the second opening in the Y-direction. A second portion of the second opening inside the isolation structures is enlarged to have a width greater than a width of a first portion of the second opening outside the isolation structures in the Y-direction.

In some embodiments, the method further includes forming bottom isolation layers on the first SiGe layer and the second SiGe layer, wherein the first source/drain feature and the second source/drain feature are formed on the bottom isolation layers; forming a sidewall dielectric layer on a surface of the bottom isolation layer exposed by the second opening and sidewalls of the first opening and the second opening; and removing the sidewall dielectric layer formed on the surface of the bottom isolation layer and partially etching the bottom isolation layer to form a third opening. The formation of the first source/drain contact further includes depositing the conductive material in the third opening.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor structure, comprising:
forming a fin structure over a substrate, wherein the fin structure comprises first semiconductor layers and second semiconductor layers alternately stacked;
forming a first source/drain trench and a second source/drain trench in the fin structure;
forming a first SiGe layer and a second SiGe layer in the first source/drain trench and the second source/drain trench, respectively;
forming a first source/drain feature and a second source/drain feature over the first SiGe layer and the second SiGe layer in the first source/drain trench and the second source/drain trench, respectively;
forming a third source/drain feature and a fourth source/drain feature over and separated from the first source/drain feature and the second source/drain feature, respectively;
removing the first semiconductor layers;
forming a gate structure to wrap around the second semiconductor layers;
forming a first interlayer dielectric (ILD) layer on a backside of the substrate;
etching the first ILD layer and the substrate to form a first opening that exposes the first SiGe layer;
removing the first SiGe layer through the first opening to form a second opening that exposes the first source/drain feature, wherein lateral dimensions of the first opening are greater than those of the second opening in an X-direction and a Y-direction, which is perpendicular to the X-direction; and
depositing a conductive material in the first opening and the second opening to form a first source/drain contact.

2. The method of claim 1, further comprising:
forming isolation structures on opposite sides of the fin structure in the Y-direction,
wherein the forming the first opening further comprises etching the isolation structures.

3. The method of claim 2, further comprising:
laterally etching the isolation structures to enlarge the first opening and the second opening in the Y-direction,
wherein a second portion of the second opening inside the isolation structures is enlarged to have a width greater than a width of a first portion of the second opening outside the isolation structures in the Y-direction.

4. The method of claim 3, wherein a first portion of the first opening inside the isolation structures is enlarged to have a width greater than a width of a second portion of the first opening inside the first ILD layer in the Y-direction.

5. The method of claim 1, further comprising:
laterally etching the substrate to enlarge the first opening and the second opening in the X-direction,
wherein a second portion of the second opening inside the substrate is enlarged to have a width greater than a width of a first portion of the second opening outside the substrate in the X-direction.

6. The method of claim 5, wherein a first portion of the first opening inside the substrate is enlarged to have a width greater than a width of a second portion of the first opening inside the first ILD layer in the X-direction.

7. The method of claim 1,
wherein the first source/drain feature and the second source/drain feature are attached to opposite sides of a first group of the second semiconductor layers; and
wherein the third source/drain feature and the fourth source/drain feature are attached to opposite sides of a second group of the second semiconductor layers over the first group.

8. The method of claim 1, further comprising:
partially recessing the first semiconductor layers exposed in the first source/drain trench and the second source/drain trench to form inner spacer recesses; and
forming inner spacers in the inner spacer recesses,
wherein one of the inner spacers is exposed by the second opening.

9. A method of forming semiconductor structure, comprising:
forming a fin structure extending in an X-direction over a substrate, wherein the fin structure comprises first semiconductor layers and second semiconductor layers alternately stacked;
forming a dummy gate structure over the fin structure and extending in a Y-direction;
forming a first SiGe layer and a second SiGe layer on opposite sides of the dummy gate structure in the X-direction;
forming a first source/drain feature and a second source/drain feature over the first SiGe layer and the second SiGe layer, respectively, wherein the first source/drain feature and the second source/drain feature are attached to a first group of the second semiconductor layers;
forming a third source/drain feature and a fourth source/drain feature attached to a second group of the second semiconductor layers,
thinning the substrate;
forming a first interlayer dielectric (ILD) layer on a backside of the substrate;
forming a first opening in the first ILD layer and the substrate to expose the first SiGe layer;
removing the first SiGe layer through the first opening to form a second opening that exposes the first source/drain feature, wherein lateral dimensions of the first opening are greater than those of the second opening in the X-direction and the Y-direction;
forming a sidewall dielectric layer on sidewalls of the first opening and the second opening; and
depositing a conductive material to fill remaining spaces of the first opening and the second opening to form a first source/drain contact.

10. The method of claim 9, further comprising:
forming isolation structures on opposite sides of the fin structure in the Y-direction,
wherein the forming the first opening further comprises partially etching the isolation structures.

11. The method of claim 10, further comprising:
laterally etching the isolation structures to enlarge the first opening and the second opening in the Y-direction,
wherein a second portion of the second opening inside the isolation structures is enlarged to have a width greater than a width of a first portion of the second opening outside the isolation structures in the Y-direction.

12. The method of claim 10, further comprising:
laterally etching the isolation structures and the first ILD layer to enlarge the first opening and the second opening in the Y-direction.

13. The method of claim 10, further comprising:
laterally etching the isolation structures and the first ILD layer to enlarge the first opening and the second opening in the X-direction.

14. The method of claim 9, further comprising:
laterally etching the substrate to enlarge the first opening and the second opening in the X-direction,
wherein a second portion of the second opening inside the substrate is enlarged to have a width greater than a width of a first portion of the second opening outside the substrate in the X-direction.

15. The method of claim 9, further comprising:
forming second ILD layers on the first source/drain feature and the second source/drain feature,
wherein the third source/drain feature and the fourth source/drain feature are formed on the second ILD layers on the first source/drain feature and the second source/drain feature, respectively,
wherein the first source/drain feature and the second source/drain feature are surrounded by the second ILD layers and are separated from the third source/drain feature and the fourth source/drain feature by the second ILD layers, respectively.

16. The method of claim 15, further comprising:
forming a contact etch stop layer over the third source/drain feature and the fourth source/drain feature;
forming a third ILD layer over the contact etch stop layer;
forming a trench extending through the third ILD layer, the contact etch stop layer, the fourth source/drain feature, and the second source/drain feature to expose the fourth source/drain feature and the second source/drain feature; and
depositing the conductive material in the trench to form a second source/drain contact.

17. A semiconductor structure, comprising:
a first transistor, comprising:
first nanostructures over a substrate, wherein the first nanostructures are spaced apart from each other in a Z-direction; and
a first source/drain feature and a second source/drain feature, attached to opposite sides of the first nanostructures in an X-direction;
a second transistor over the first transistor, wherein the second transistor comprises:
second nanostructures over the first nanostructures, wherein the second nanostructures are spaced apart from each other in the Z-direction; and
a third source/drain feature and a fourth source/drain feature, attached to opposite sides of the second nanostructures in the X-direction and being over the first source/drain feature and the second source/drain feature, respectively;
a gate structure wrapped around the first nanostructures and the second nanostructures; and
a first source/drain contact, passing through the substrate and being in contact with the first source/drain feature,
wherein the first source/drain contact comprises a first portion in contact with the first source/drain feature and a second portion below the first portion,
wherein a Y-direction width of the second portion is greater than a Y-direction width of the first portion in a Y-direction, which is perpendicular to the X-direction.

18. The semiconductor structure of claim 17, further comprising:
a sidewall dielectric layer formed on sidewalls of the first source/drain contact, wherein the sidewall dielectric layer separates the first source/drain contact from the substrate.

19. The semiconductor structure of claim 17, further comprising:
isolation structures formed in the substrate and on opposite sides of the first source/drain contact in the Y-direction; and
a first interlayer dielectric (ILD) layer below the substrate and the isolation structures.

20. The semiconductor structure of claim 19,
wherein the second portion of the first source/drain contact has a first sub-portion surrounded by the isolation structures in the Y-direction and a second sub-portion surrounded by the first ILD layer,
wherein a Y-direction width of the first sub-portion of the second portion is greater than a Y-direction width of the second sub-portion of the second portion in the Y-direction.
